(19) United States
(12) Patent Application Publication
(10) Pub. No.: US 2026/0266915 A1
(43) Pub. Date: Sep. 10, 2026

(54) BATTERY ELECTRICAL IMPEDANCE MEASUREMENT SYSTEMS, APPARATUSES, AND METHODS

(71) Applicant: Analog Devices International Unlimited Company, Limerick (IE)

(72) Inventors: Colin G. LYDEN, Baltimore (IE); Brendan M. DALY, Farnanes (IE); Patrick PRATT, Mallow (IE)

(21) Appl. No.: 18/847,113

(22) PCT Filed: Mar. 13, 2023
(86) PCT No.: PCT/EP2023/056393

§ 371 Date: Sep. 13, 2024

Related U.S. Application Data
(60) Provisional application No. 63/319,460, filed on Mar. 14, 2022.

(51) Int. Cl. G01R 31/389; G01R 31/371; G01R 31/3835; G01R 31/396; H01M 10/42

(52) U.S. Cl. CPC G01R 31/389; G01R 31/371; G01R 31/3835; G01R 31/396; H01M 10/4285; H01M 2010/4271

(57) ABSTRACT

Technologies are provided for impedance measurements. In one aspect, a method for measuring impedance of an individual cell in a series of cells may include combining output voltages measured from the individual cell and output voltages measured from one or more neighboring cells before correlation with a stimulus current. The method may further include controlling switches associated with the individual cell and neighboring cell(s) in a certain sequence to generate the stimulus current and the output voltages for measurements. In another aspect, a local battery management system may measure voltage waveforms associated with a battery pack including a series of cells in response to a stimulus current and wirelessly transmit the measured response waveforms to a remote battery management system. The remote battery management system may calculate the impedance of the cells based on the measured voltage waveforms and stimulus current.

### CROSS-REFERENCE TO RELATED APPLICATION

This application is a 35 U.S.C. § 371 National Stage Application of International Patent Application No. PCT/EP2023/056393, filed Mar. 13, 2023, which claims the benefit of and priority to U.S. Provisional Patent Application No. 63/319,460, filed Mar. 14, 2022, the contents of each of which applications are hereby incorporated by reference herein in their entireties.

### TECHNICAL FIELD OF THE DISCLOSURE

The present disclosure generally relates to battery management systems, and more particularly to measuring electrical impedance of battery packs, where the electrical impedance can be composed of a resistance and/or a reactance.

### BACKGROUND

A battery pack may typically include battery cells (which may be referred to simply as cells) that are physically connected in series and/or parallel to provide a certain desired power. Large battery packs are commonly used in hybrid and/or electrical vehicles, for example, to generate high voltages for driving components such as automotive motors in the vehicles. Batteries are complex electrochemical components with subtle behaviors. Battery performances may depend heavily on internal and external conditions (e.g., aging, temperature, etc.). In order to keep track of these performances and battery states, a battery pack may be equipped with a battery management system. The battery management system may be responsible for providing safe use of the battery and estimating the states of the battery pack, such as its state of health (SOH), state of power (SOP), and state of charge (SOC). The SOC may provide information about the current amount of energy stored in the battery pack. The SOP may indicate the battery capability of providing the required power. The SOH is a figure of merit that indicates the battery level of degradation. Due to the complex behavior of the battery, estimating battery SOC, SOP and SOH can be challenging.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 is a schematic diagram illustrating an example of a battery cell monitoring and cell balancing configuration;

FIG. 2 is a schematic diagram illustrating an example of a battery cell impedance measurement configuration that utilizes a dedicated sense path;

FIG. 3A is a schematic diagram illustrating an example of a battery cell impedance measurement configuration for a stack of cells during a first state, according to some aspects of the disclosure;

FIG. 3B is a schematic diagram illustrating an example of a battery cell impedance measurement configuration for a stack of cells during a second state, according to some aspects of the disclosure;

FIG. 3C is an example of a timing diagram of control signals in a battery management system, according to some aspects of the disclosure;

FIG. 3D is a schematic diagram illustrating an example of a battery cell impedance measurement configuration for a stack of cells, according to some aspects of the disclosure;

FIG. 4 is a schematic diagram illustrating an example of a correlator for battery impedance measurement, according to some aspects of the disclosure;

FIG. 5 is a schematic diagram illustrating an example of a wireless battery management system, according to some aspects of the disclosure;

FIG. 6A is a sequence diagram illustrating an example of a battery impedance measurement method, according to some aspects of the disclosure;

FIG. 6B is a diagram of an example of a circuit model fitting scenario, according to some aspects of the present disclosure;

FIG. 6C is a diagram of an example of another circuit model fitting scenario, according to some aspects of the present disclosure;

FIG. 7 is a sequence diagram of an example of a battery impedance measurement method, according to some aspects of the disclosure;

FIG. 8 is a flow diagram of an example of a battery impedance measurement method, according to some aspects of the disclosure;

FIG. 9 is a flow diagram of an example of a battery impedance measurement method, according to some aspects of the disclosure; and

FIG. 10 is a block diagram of an example of a processing system, according to some aspects of the present disclosure.

### DETAILED DESCRIPTION

### Overview

The systems, methods, and devices of this disclosure each have several innovative embodiments. Such systems, methods, and devices, individually or in combination, provide the desirable attributes disclosed herein and also the resulting improvements over existing technologies for measurement of electrical impedance of battery packs. Details of one or more implementations of the subject matter described in this specification are set forth in the description below and the accompanying drawings.

A battery pack may include one or more battery modules or stacks connected in parallel and/or series, where each module or stack may include a plurality of battery cells connected in series. For the series connection, the positive terminal of one cell may be connected to the negative terminal of the next cell in the series. Ideally, each individual battery cell in the pack or module may contribute equally to the generated power. However, even battery cells of the same chemistry with the same physical size and shape can have different characteristics such as different total capacities, different internal resistances, different self-discharge rates, etc. In addition, different battery cells can age differently, adding another variable in the battery life. For example, a battery pack may initially have fairly well-matched cells. But over time, the cell matching may degrade due to charge/discharge cycles, elevated temperatures, and general aging. A weak battery cell may charge and discharge faster than a stronger or higher capacity battery cell. As such, the performance of a battery module may be limited by the lowest capacity cell in the module. For instance, once the weakest cell is depleted, the entire module may be effectively depleted.

The state of each individual battery cell in the module may be determined based on an SOC measurement on the battery cell, which SOC measurement measures the ratio of remaining charge in the battery cell to cell capacity of the battery cell. An SOC measurement may utilize battery measurements, such as voltages, integrated charges and discharge currents, and temperatures to determine the charge remaining in the battery. In some examples, a battery management system may be used to monitor and manage the SOC and/or SOH of the battery pack. Additionally, the battery management system may perform cell balancing (e.g., active balancing or passive balancing) to improve the battery pack performance. These SOC and/or SOH measurements and cell balancing can provide healthy battery state of charge independent of the cell capacity, minimize cell-to-cell state of charge mismatch, and/or minimize effects of cell aging (where aging can result in lost capacity, for example).

Cell balancing is a technique that can improve battery life by maximizing the capacity of a battery pack with multiple cells in series, ensuring that all or most all of the energy of the battery pack is available for use. One type of cell balancing is passive balancing. Passive balancing may allow all series-connected battery cells in a module (or pack) to appear to have the same capacity as the weakest cell in the module. Using a relatively low current, passive cell balancing can drain a small amount of energy from the high SOC cells during the charging cycle so that all cells charge to their maximum SOC. To that end, in some cases, a unique switch and a unique bleed resistor connected in series may be connected in parallel with each individual battery cell. For instance, each terminal of each of the plurality of cells in a module may be connected to a conducting element (e.g., wire) in a ladder configuration with adjacent cells in the series sharing the same conducting element. A series-connected switch and bleed resistor may be connected across each pair of conducting elements to facilitate recharge and/or discharge of a corresponding battery cell. Further, an analog-to-digital converter (ADC) may be connected across each pair of conducting elements to read the output voltage of each corresponding cell. A high SOC cell in the battery pack may have a higher output voltage than a low SOC cell in the battery pack. Excess energy or charge in the high-SOC cell can be periodically burnt off via the corresponding bleed resistor (with the corresponding switch closed) so that all cells in the battery pack may have voltages that slightly differ (e.g., are within approximately one to a few millivolts (mVs)) from each other throughout the life of the battery pack.

Measuring cell voltages alone may not provide information related to the SOH of the battery pack. The health status of a battery pack may be indicated by the battery cell impedances. In this disclosure, battery cell impedance refers to an electrical impedance of the battery cell, where the electrical impedance is generally composed of a resistance and a reactance. In some cases, the electrical impedance arises from purely resistive sources. In other cases, the electrical impedance arises from purely reactive sources. In yet other cases, the electrical impedance arises from a combination of resistive sources and reactive sources. In some examples, a battery management system may utilize an electrical impedance spectroscopy (EIS) approach for battery impedance estimation. In this regard, the battery management system may measure the cell impedance of a battery cell by applying a known stimulus current to each battery cell and measuring corresponding changes in the cell output voltages. To measure the impedance at a specific frequency, the stimulus current waveform may be generated such that a significant amount of energy may be present at that frequency and the measured cell output voltages can be filtered to suppress any unwanted signals at other frequencies. In some examples, the frequencies of interest for battery impedance measurements may be in the range of about 1 millihertz (mHz) to greater than about 10 kilohertz (kHz).

Battery impedances may be very small by design. As an example, the impedance of an electric vehicle cell may be of the order of about 1 milliohm (m Ω). To measure these small battery impedances, a large stimulus current, for example, of the order of about 100 milli-ampere (mA) or more (e.g., 10 ampere (A)), may typically be used. To minimize the cost and size of a battery pack, it may be desirable to utilize existing components of the battery pack for EIS measurements. For instance, the cell balancing switches and the bleed resistors can be reused for generating stimulus currents for impedance measurements and the ADCs can be reused for reading cell output voltages for impedance calculations. However, the existing conducting elements or wires (that connect bleed resistors and switches to correspond cells) may have a substantially larger impedance than the battery cell impedances (e.g., by a factor of 10 or more), and thus can cause errors in the voltage measurements that are used for determining the cell impedance. A solution to the wiring impedance problem is to utilize an extra pair of wires to connect each cell to a corresponding ADC for output voltage measurements. That is, one pair of wires may be used to provide the stimulus current and a separate pair of wires may be dedicated for reading output voltages of the cell but not for carrying the stimulus current. The extra wiring can add to the cost and weight of the battery, and thus may be undesirable.

Aspects of the present disclosure provides mechanisms for measuring electrical impedances of battery cells accurately without requiring separate wires dedicated for cell output voltage measurements and for cell stimulation. As mentioned, the electrical impedances can be composed of a resistance and a reactance. In some cases, the reactance includes an inductance, and thus, the electrical impedance may be composed, partially or entirely, of inductance. One aspect of the present disclosure provides a battery management system for measuring impedances of a battery pack comprising a plurality of cells connected in series. As explained above, each terminal of each of the plurality of cells may be connected to a conducting element (e.g., wire) in a ladder configuration with adjacent cells sharing the same conducting element. A series-connected switch and bleed resistor may be connected across each pair of conducting elements to facilitate recharge and/or discharge of a corresponding battery cell (e.g., for cell balancing). The battery management system may reuse the cell balancing components (e.g., the switches and bleeding resistors) to generate stimulus for cell impedance measurements. To address the wire impedance issue discussed above, the battery management system may determine an impedance for an individual cell in the series by combining output voltages measured from the individual cell and output voltages measured from one or more neighboring cells (e.g., a first cell of the plurality of cells) before correlation with the stimulus. The battery management system may control switches associated with the individual cell and the neighboring cell(s) in a certain sequence, for example, including a first state and a second state.

For instance, during the first state while a first switch associated with the first cell (a neighboring cell) and a second switch associated with the individual cell (under impedance measurement) are opened, a first voltage (e.g., V_{cell1_OCV}) associated with the first cell may be measured across a first conducting element and a second conducting element. The first conducting element and the second conducting element may be connected to different terminals of the first cell, and the first switch and a first bleeding resistor may be connected across the first and second conducting elements (e.g., in parallel with the first cell). Because the first cell is a neighboring cell to the individual cell, the individual cell may share a conducting element with the first cell. For instance, one terminal of the individual cell may be connected to the second conducting element (shared with the first cell) and the opposite terminal of the individual cell may be connected to a third conducting element, and the second switch and a second bleeding resistor may be connected across the second and third conducting elements (e.g., in parallel with the individual cell).

During the second state while the first switch (associated with the first cell) is opened and the second switch (associated with the individual cell) is closed, a second voltage associated with the individual cell may be measured across the second and third conducting elements, and a third voltage associated with the first cell may be measured across the first and second conducting elements. Closing the second switch may generate a stimulus current. Moreover, the third voltage (measured across the first and second conducting elements) may include

$${V}_{OCV}^{( 1 )}$$

and a voltage drop (e.g., V_{Rp2}) caused by the stimulus current flowing through the second conducting element. That is, the second voltage may be represented by

$${V}_{OCV}^{( 1 )} - {V}_{Rp 2} .$$

Further, the second voltage (measured across the second and third conducting elements) may include a voltage

$$( e . g . , {V}_{STIM}^{( 2 )} )$$

of the individual cell due to the stimulus current and the voltage drop (e.g., V_{Rp2}) across the second conducting element. That is, the second voltage may be represented by

$${V}_{STIM}^{( 2 )} - {V}_{Rp 2} .$$

The battery management system may calculate an impedance of the individual cell based at least in part on the first, second, and third voltages.

In some aspects, as part of calculating the impedance of the individual cell, the battery management system may determine the voltage drop V_{Rp2} due to an impedance (or parasitic resistance) of the second conducting element based on a difference between the first voltage and the third voltage and then adjust the second voltage using the determined voltage drop V_{Rp2}. Further, during the first state while the first and second switches are opened, a fourth voltage

$$( e . g . , {V}_{OCV}^{( 2 )} )$$

associated with the individual cell may be measured across the second and third conducting elements. The battery management system may calculate the impedance of the individual cell further based on a voltage change between the fourth voltage and the adjusted second voltage and the amount of current flowing through the second bleed resistor during the second state (while the second switch associated with the individual cell is closed). In some aspects, as part of calculating the impedance, the battery management system may correlate the adjusted second voltage with a switching frequency of the second switch.

In some aspects, the individual cell under test (or impedance measurement) may be between two cells in the series of cells. That is, the individual cell may have another neighboring cell and may share the third conducting element with the other neighboring cell. The battery management system may account for the voltage drop across the third conducting element using similar mechanisms as for the voltage drop across the second conducting element. In general, because the battery management system utilizes output voltages of neighboring cells to address the wire impedance issue, the battery management system can simultaneously measure impedance for multiple cells (e.g., stimulated cells) of the plurality of cells as long as the multiple cells are spaced apart from each other by two other cells (e.g., non-stimulated cells) of the plurality of cells.

Accordingly, the present disclosure provides systems, devices, techniques, and mechanisms that, individually or collectively, can advantageously measure impedances of cells in a battery pack accurately using existing cell balancing components, and without adding additional wires, using the sequence (with the first state and second state) described herein, and thus can reduce size, weight, and/or cost of the battery pack. Additionally, or in some aspects, one or several of the measurement sequences described herein may allow for a small stimulus current to be used. For instance, a smaller stimulus current, for example, of about 200 mA, may be used for the stimulation instead of a substantial 10 A stimulus current. Further, reducing wiring in a system may also improve reliability of the system. For example, the improved reliability can be especially advantageous when the battery system is used in a vehicle. Thus, aspects of the present disclosure improve existing technologies for monitoring various states of battery cells that may be present in a vehicle (electric or otherwise).

A further aspect of the present disclosure provides a wireless battery management system, for example, including a local battery management system and a remote battery management system. The local battery management system may be located within a battery pack (e.g., as an integral part of the battery pack) and the remote battery management system may be located at a remote location from the battery pack. The battery pack may include a plurality of battery cells connected in series. The local battery management system may generate stimulus currents (with certain waveforms) for each individual battery cell and may measure response waveforms from each individual battery cell (responsive to a corresponding stimulus). The local battery management system may wirelessly transmit the measured response waveforms (e.g., including one or more sequence of voltage samples) to the remote battery management system. The remote battery management system may calculate an impedance for each cell based on a corresponding response waveform received from the local battery management system and a corresponding stimulus waveform that triggers the response waveform. In some aspects, the remote battery management system may calculate the impedance for an individual cell using circuit model fitting techniques. In some aspects, the remote battery management system may configure the local battery management system in generating the stimulus, for example, by wirelessly transmitting stimulus current configuration information (e.g., a stimulus modulation frequency, duty cycle, or the like) to the local battery management system, and the local battery management system may generate the stimulus current waveform based on the configuration information. In other aspects, the local battery management system may determine a stimulus current configuration and wirelessly transmit the stimulus current configuration information (e.g., a stimulus modulation frequency, duty cycle, or the like) to the remote battery management system.

Accordingly, the present disclosure provides systems, devices, techniques, and mechanisms that, individually or collectively, can advantageously improve computational efficiency of commonplace techniques by offloading computation intensive calculations to a remote processor (at the remote battery management system, for example) instead of performing impedance calculations at the local battery management system (which may be more resource limited than the remote processor). Further, because the intensive impedance calculations are performed at the remote battery management system, the local battery management system may be implemented on a light-weight processor (such as a microprocessor) located closed to the battery pack, and thus the systems, devices, techniques, and mechanisms described herein can reduce the amount of wiring at the battery pack.

Simply for purposes of illustration, in this disclosure and annexed drawings, various aspects of the measurement of battery cell impedance are illustrated with circuitry having resistors that permit or otherwise facilitate such a measurement. The disclosure, of course, is not limited in that respect, and the principles and practical applications of this disclosure still can be applied to circuitry having those resistors replaced with impedances. The impedances can include inductances, and in some cases, the impedances can be composed entirely of inductances.

### Example Battery Cell Monitoring and Cell Balancing Configuration

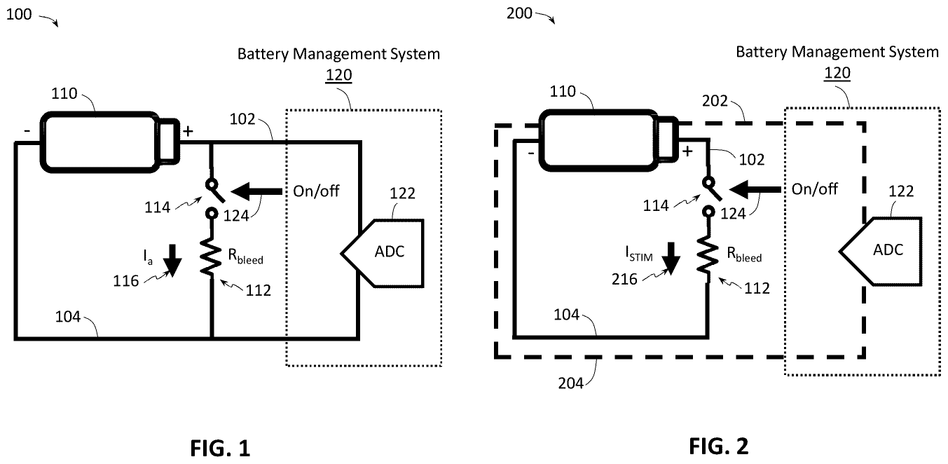

FIG. 1 is a schematic diagram illustrating an example battery cell monitoring and cell balancing configuration 100. The battery cell monitoring and cell balancing configuration 100 may be used in a wide variety of applications, such as for electrical vehicles. As shown in FIG. 1, the configuration 100 may include a battery cell 110 (which also may be referred to as cell 110) and a battery management system 120. The battery cell 110 may be any suitable type of batteries. In some examples, the battery cell 110 may be a lithium-ion cell. The battery management system 120 may include an ADC 122. The ADC 122 may be any suitable type of ADC (e.g., a successive approximation register (SAR) ADC, or a sigma-delta ADC). In the illustrated example of FIG. 1, the ADC 122 is a differential ADC, where one terminal (a positive terminal shown by the “+” symbol) of the battery cell 110 may be coupled to the ADC 122 via a conducting element 102 and an opposite terminal (a negative terminal shown by the “−” symbol) of the battery cell 110 may be coupled to the ADC 122 via another conducting element 104. The conducting elements 102 and 104 may be any suitable wires. The battery management system 120 may monitor output voltages of the battery cell 110, for example, by reading an output of the ADC 122. That is, the ADC 122 may convert an output voltage of the cell 110 across the conducting element 102 and the conducting element 104 into a digital value. The battery management system 120 may monitor the SOC of the battery cell 110 based on the output voltages of the battery cell.

As further shown in FIG. 1, the configuration may include a switch 114 connected in series with a resistor 112 (which may be referred to as a bleed resistor), where the series-connected switch 114 and bleed resistor 112 are connected across the conducting elements 102 and 104 (in parallel with the output of the battery cell 110). The bleed resistor 112 and the switch 114 may be used for cell balancing. Although a resistor is shown in FIG. 1, the disclosure is not limited in that respect. Indeed, in some cases, the resistor 112 can be replaced by a two-terminal electrical component including a resistive element or an inductive element, or a combination of both. Such a two-terminal electrical component has an electrical impedance that can be represented as a complex number having a real part corresponding to a resistance and an imaginary part corresponding to a reactance (which can be finite or null). For simplicity, FIG. 1 illustrates a single battery cell 110. However, a battery pack may typically have multiple battery cells similar to the battery cell 110 connected in series, for example, the negative terminal of the battery cell 110 may be connected to the positive terminal of a neighboring cell (below the battery cell 110 in the configuration 100) and the positive terminal of the battery cell 110 may be connected to the negative terminal of another neighboring cell (on top of the battery cell 110 in the configuration 100). In some examples, a battery pack may include about 12 battery cells similar to the battery cells 110 connected in series. While FIG. 1 illustrates the switch 114 and the bleed resistor 112 as external components to the battery management system 120, in some cases, the switch 114 and the bleed resistor 112 can be part of the battery management system 120.

As is described herein, a battery management system may perform cell balancing (e.g., passive cell balancing) to improve the performance of a battery pack. For instance, each terminal of each cell in the battery pack may be connected to a conducting element similar to the conducting elements 102 and 104 in a ladder configuration with adjacent cells sharing the same conducting element. A series-connected switch and bleed resistor similar to the series-connected switch 114 and bleed resistor 112 may be connected across each pair of conducting elements to facilitate recharge and/or discharge of a corresponding battery cell. Further, the battery management system 120 may include an ADC similar to the ADC 122 connected across each pair of conducting elements to read the output voltage of each corresponding cell. The battery management system 120 may include any suitable number of ADCs 122 for the output voltage readouts. In some examples, the battery management system 120 may include a dedicated ADC 122 for each battery cell 110. In other examples, the battery management system 120 may include an ADC 122 for a subset of the battery cells in the pack.

For cell balancing, the bleed resistors (e.g., the bleed resistor 112) may be used to ensure that the cells are maintained at a relatively uniform charge state. To that end, cells with higher open circuit voltages are discharged until the spread of open circuit voltages is sufficiently reduced. That is, the ADC(s) in the battery management system 120 may monitor the output voltages of each individual cell and may control the opening and/or closing of the switches (e.g., the switch 114) of each cell for cell balancing. As shown, the battery management system 120 may generate a control signal 124 to control the opening and/or closing of the switch 114. For instance, if the battery management system 120 determines that the output voltage of the cell 110 is higher than other cells in the pack, the battery management system 120 may close the switch 114 and cause a current 116 (shown as Ia) to flow through the bleed resistor 112 until the charges in the battery cell 110 matches the lower energy cells in the pack.

As is described herein, measuring cell voltages alone may not provide information related to the SOH of the battery pack. The health status of a battery pack is indicated by the battery cell impedances. For instance, the battery management system 120 may utilize an EIS approach for battery cell impedance measurement. It may be desirable to utilize existing components of a battery pack for EIS measurements to reduce the size and/or cost of battery pack. For instance, the cell balancing switches and the bleed resistors in a battery pack can be reused for generating stimulus currents for impedance measurements, and the ADC(s) used for measuring cell voltages in a battery management system can be reused for reading cell output voltages for impedance calculations. However, the existing conducting elements or wires (that connect bleed resistors and switches to correspond cells) may have a substantially larger impedance (e.g., by a factor of 10 or more) than the battery cell impedances, and thus can cause errors in the voltage measurements that are used for determining the cell impedance. One approach to avoiding such errors is to utilize a dedicated path or wires for measurements as is described below with reference to FIG. 2.

### Example Battery Impedance Measurement Configuration with Dedicated Sensing Wires

FIG. 2 is a schematic diagram illustrating an example battery cell impedance measurement configuration 200 that utilizes a dedicated sense path. The battery cell impedance measurement configuration 200 of FIG. 2 shares many elements with the battery cell monitoring and cell balancing configuration 100 of FIG. 1. As such, for the sake of brevity, a discussion of these elements is not repeated, and these elements may take the form of any of the embodiments disclosed herein. Again, although a resistor 112 is shown in FIG. 2, the disclosure is not limited in that respect. Indeed, in some cases, the resistor 112 can be replaced by a two-terminal electrical component including a resistive element or an inductive element, or a combination of both. Such a two-terminal electrical component has an electrical impedance that can be represented as a complex number having a real part corresponding to a resistance and an imaginary part corresponding to a reactance (which can be finite or null).

In the configuration 200, the battery management system 120 may measure the impedance of the battery cell 110 by applying a known stimulus current to the battery cell and measuring a corresponding change in the output voltages of the battery cell 110. The configuration 200 may reuse the cell balancing switch 114 and the bleed resistor 112 to generate a stimulus current 216 represented by ISTIM. In some examples, the battery management system 120 may desire to measure the impedance of the battery cell 110 at a specific frequency. To that end, the battery management system 120 may generate the stimulus current 216 with a waveform having a significant amount of energy present at the desired frequency, for example, by switching (opening and closing) the switch 114 at that frequency. The closing and opening of the switch 114 may produce a modulated current waveform (e.g., a square waveform). The frequency at which the switch 114 opens and closes may be referred to as a modulation frequency.

When the stimulus current 216 flows through the conducting elements 102 and 104, a voltage drop may occur at the conducting element 102 and another voltage drop may occur at the conducting element 104. As explained above, the impedance of the battery cell 110 may be substantially smaller than the impedance of the conducting elements 102 and 104 (e.g., by an order of 10 or higher). Thus, if the same conducting elements 102 and 104 are used for carrying the stimulus current 216 and measuring the voltage of the battery cell 110, the voltage drops at the conducting elements 102 and 104 can cause errors in the measured output voltages that are used for impedance calculations. To overcome the wire impedance issue, the configuration 200 utilizes a separate pair of conducting elements 202 and 204 (shown by the dashed lines) specifically for voltage measurements, where the positive terminal of the battery cell 110 is coupled to the ADC 122 via the conducting element 202 and the negative terminal of the battery cell 110 is coupled to the ADC 122 via the conducting element 204. That is, the conducting elements 202 and 204 are dedicated for voltage measurement or sensing but not for carrying the stimulus current 216. The use of the dedicated conducting elements 202 and 204 for impedance measurement may be referred to as a 4-wire solution as each cell 110 may be connected to 4 wires (e.g., the conducting elements 102, 104, 202, and 204).

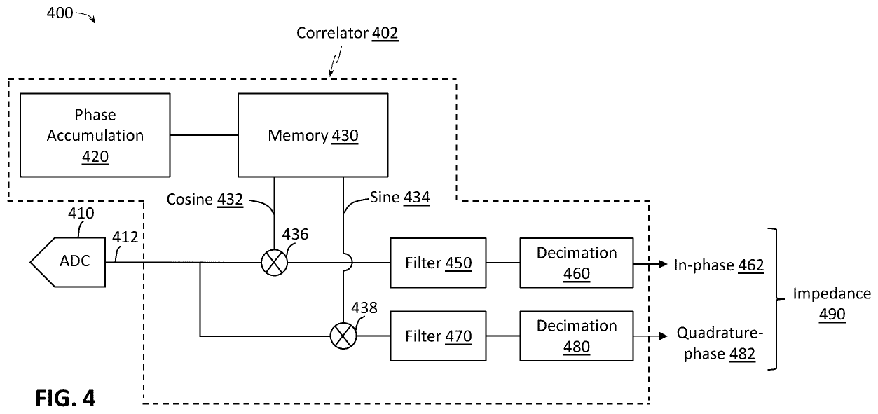

To calculate the impedance of the cell 110, the battery management system 120 may measure the output voltages of the battery cell 110 (e.g., by reading the ADC 122 outputs) when the switch 114 is opened and when the switch 114 is closed. The battery management system 120 may determine the resulting change in the cell 110 output voltages (e.g., between a first output voltage measured during which the switch 114 is opened and a second output voltage measured during which the switch 114 is closed). The battery management system 120 may correlate the voltage change with the stimulus current 216 to determine the impedance of the battery cell 110. Mechanisms for correlating voltage changes to stimulus current are discussed more fully below with reference to FIG. 4.

Utilizing the additional conducting elements 202 and 204 for voltage measurement or sensing can provide accurate battery cell impedance measurements but may increase the size, weight, and/or cost. Accordingly, it may be undesirable to add extra wires (e.g., the dedicated conducting elements 202 and 204) to support battery cell impedance measurements.

### Example Battery Impedance Measurement Configuration and Operation Sequence without Utilizing Dedicated Sensing Wires

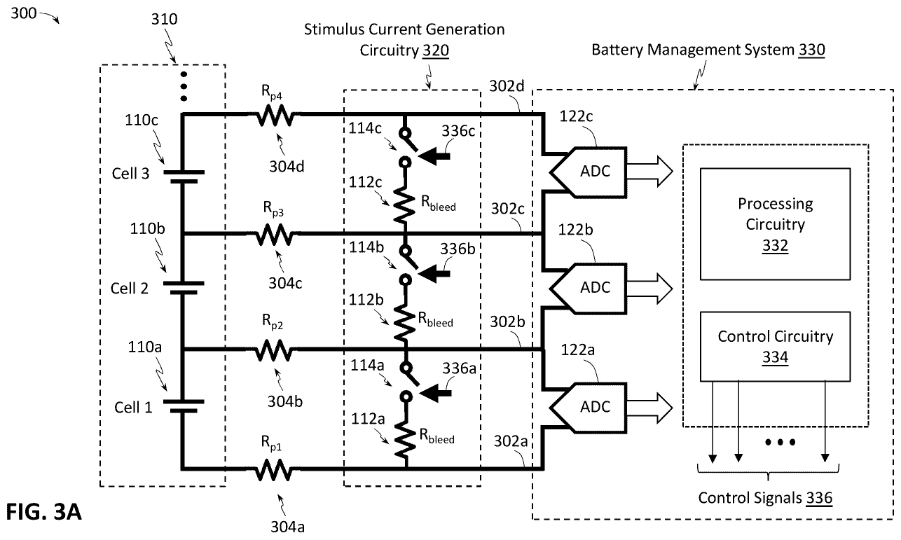

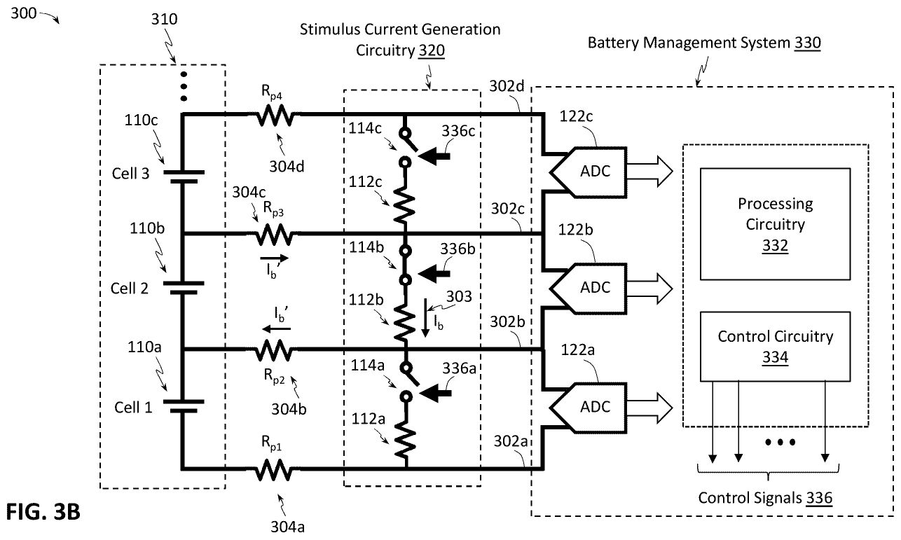

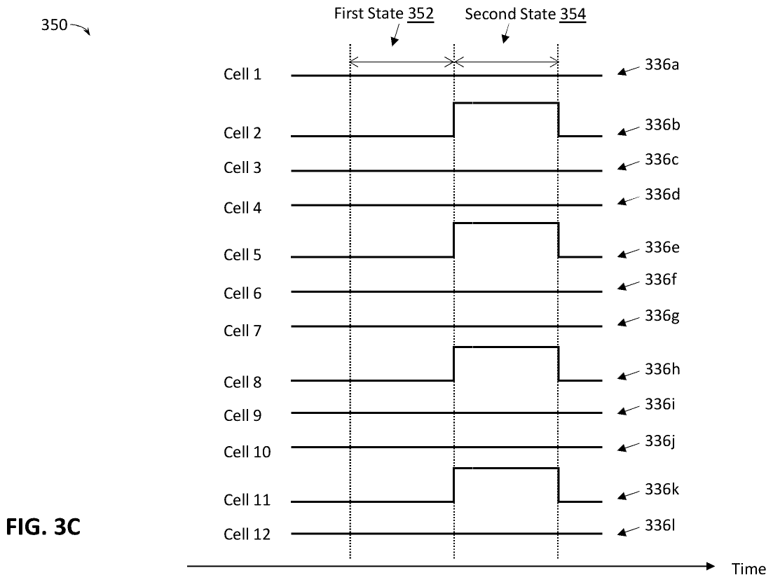

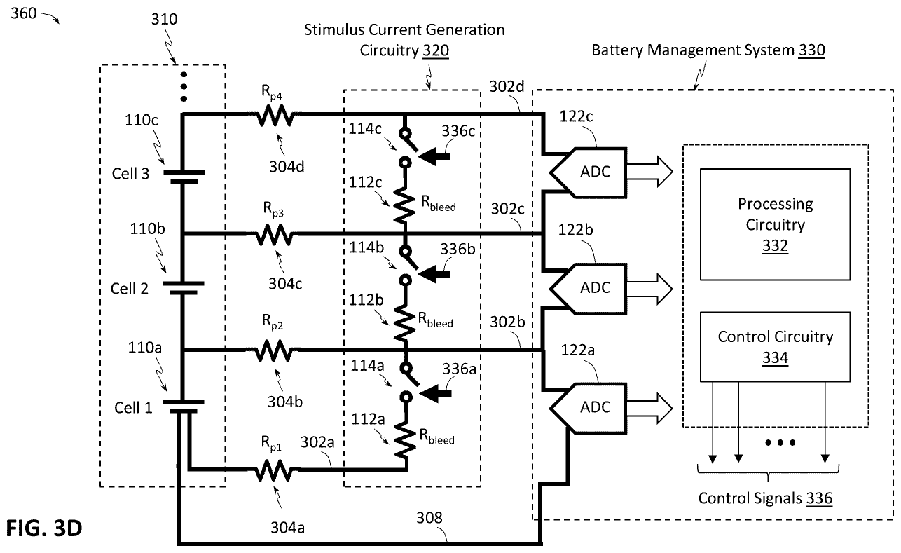

FIGS. 3A-3C are discussed in relation to each other to illustrate an example battery impedance measurement configuration and operation sequence that can provide accurate impedance measurements for a stack of battery cells 110 without utilizing dedicated sensing wires. According to embodiments of the present disclosure, a battery management system (e.g., the battery management system 120) may control switches associated with an individual cell and neighboring cell(s) (of a plurality of cells connected in series in a battery pack) in a certain sequence (e.g., including a first state and a second state) to generate a stimulus current for battery cell impedance measurements and may combine output voltages measured from the individual cell and output voltages measured from the neighboring cell(s) before correlation with the stimulus.

FIG. 3A is a schematic diagram illustrating an example battery cell impedance measurement configuration 300 for the stack of battery cells 110 during a first state, according to some aspects of the disclosure. The configuration 300 of FIG. 3A shares many elements with the battery cell monitoring and cell balancing configuration 100 of FIG. 1. As such, for the sake of brevity, a discussion of these elements is not repeated, and these elements may take the form of any of the embodiments disclosed herein.

As shown in FIG. 3A, the configuration 300 may include a battery pack 310, stimulus current generation circuitry 320, and a battery management system 330. The battery pack 310 may include a plurality of battery cells 110 connected in series. Each battery cell of the plurality of battery cells may be referred to herein as a cell. The stimulus current generation circuitry 320 may reuse cell balancing components such as switches 114 and resistors 112 of the battery pack 310 for stimulus current generation. The battery management system 330 may include ADCs 122, processing circuitry 332 and control circuitry 334. While FIG. 3A illustrates the stimulus current generation circuitry 320 external to the battery management system 330, in some instances, the stimulus current generation circuitry 320 can be part of the battery management system 330. For example, the battery management system 330 and the stimulus current generation circuitry 320 may together be implemented as an application specific integrated circuit (ASIC). In some instances, the battery management system 330 may communicate with the stimulus current generation circuitry 320 over a wired connection (e.g., using serial peripheral interface (SPI) or any suitable wired communication protocol).

For simplicity, FIG. 3A illustrates three cells 110 (shown as Cell 1 110a, Cell 2 110b, and Cell 3 110c), three ADCs 122a, 122b, and 122c, and three pairs of series-connected switch 114 and bleed resistor 112 (shown as series-connected switch 114a and bleed resistor 112a, series-connected switch 114b and bleed resistor 112b, and series-connected switch 114c and bleed resistor 112c). However, the configuration 300 can be scaled to include any suitable number of cells 110 (e.g., about 2, 4, 5, 6, 7, 8, 9, 10, 11, 12 or more) connected in series and corresponding ADCs 122 and series-connected switch 114 and bleed resistor 112. While FIG. 3A illustrates that each cell 110 is coupled to a separate ADC 122, in some aspects, a group of cells may share the same ADC 122. For instance, for a battery pack 310 with twelve series-connected cells 110, each group of six cells 110 may be coupled to the same ADC 122 (e.g., for cell output voltage measurements). That is, the battery pack 310 may include two ADCs 122. As an example, an ADC 122 may be coupled to a group of six cells 110 via a multiplexer and may read out a voltage for each of the cells 110 in the group sequentially. In this regard, the multiplexer may select one ADC channel associated with a respective cell 110 in the group at a time to perform the ADC readout. Although a resistor 112a, a resistor 112b, and a resistor 112c are shown in FIG. 3A, the disclosure is not limited in that respect. Indeed, in some cases, one or more of the resistors 112a, 112b, and 112c can be replaced by a respective two-terminal electrical component including a resistive element or an inductive element, or a combination of both. Such a two-terminal electrical component has an electrical impedance that can be represented as a complex number having a real part corresponding to a resistance and an imaginary part corresponding to a reactance (which can be finite or null).

As is shown in FIG. 3A, each terminal of each cell 110 in the battery pack 310 may be connected to a conducting element 302 (e.g., similar to the conducting elements 102 and 104) in a ladder configuration with adjacent cells 110 sharing the same conducting element 302. More specifically, the positive terminal and the negative terminal of the cell 110c are coupled to the conducting element 302d and conducting element 302c, respectively; the positive terminal and the negative terminal of the cell 110b are coupled to the conducting element 302c and conducting element 302b, respectively; and the positive terminal and the negative terminal of the cell 110a are coupled to the conducting element 302b and conducting element 302a, respectively. Further, the cell 110c is connected in parallel with the ADC 122c via the conducting elements 302d and 302c, and the switch 114c and bleed resistor 112c are connected in series across the conducting elements 302d and 320c. In a similar way, the cell 110b is connected in parallel with the ADC 122b via the conducting elements 302c and 302b, and the switch 114b and bleed resistor 112b are connected in series across the conducting elements 302c and 320b, where the conducting element 302c is shared between the cell 110c and the cell 110b; and the cell 110a is connected in parallel with the ADC 122a via the conducting elements 302b and 302a, and the switch 114a and bleed resistor 112a are connected in series across the conducting elements 302b and 320a, where the conducting element 302b is shared between the cell 110b and the cell 110a.

The control circuitry 334 may generate control signals 336 to control the opening and/or closing of the switches 114 for stimulus current generation. For instance, the control signals 336 may include a control signal 336a, 336b, and 336c, where the control signal 336a may control the switch 114a to generate a stimulus current for the cell 110a, the control signal 336b may control the switch 114b to generate a stimulus current for the cell 110b, and the control signal 336c may control the switch 114c to generate a stimulus current for the cell 110c. The switching (opening and closing) of a switch 114 may modulate a current in a corresponding cell 110. The resulting changes in the cell output voltage from the switching can be determined from voltages measured by a corresponding ADC 122. As an example, the control signal 336b may cause the switch 114b to open for a first time interval and then close for a second time interval to generate a stimulus current for the cell 110b. The ADC 122b may read a first output voltage of the cell 110b while the switch 114b is opened and read a second output voltage of the cell 110b while the switch 114b is closed. The processing circuitry 332 may receive the voltage readouts (e.g., the first output voltage and the second output voltage) from the ADCs 122. The processing circuitry 332 may correlate the voltage changes (between the first output voltage and the second output voltage) with the changes in current due to the switching. The processing circuitry 332 may calculate the impedance of the cell 110b based on the voltage changes and the current changes.

As is described herein, each of the conducting elements 302 may have a parasitic resistance when a current flows across the conducting element 302, causing a voltage drop. Thus, cell output voltages measured at the ADC 122 may be inaccurate. As shown, the conducting element 302a may have a parasitic resistance 304a shown as Rₚ₁, the conducting element 302b may have a parasitic resistance 304b shown as Rₚ₂, the conducting element 302c may have a parasitic resistance 304c shown as Rₚ₃, and the conducting element 302d may have a parasitic resistance 304d shown as Rₚ₄. The battery management system 330 may compensate or account for the parasitic resistances 304 in the conducting elements 302 when determining impedances for the cells 110. To that end, the battery management system 330 may determine an impedance for each individual cell 110 by controlling the switches 114 associated with the individual cell 110 and its neighboring cells 110 in a certain sequence (e.g., including the first state and the second state) and combining cell output voltages of the individual cell 110 and its neighboring cells 110 measured from the first state and the second state. For simplicity, the sequence illustrated in FIGS. 3A and 3B and the calculations discussed below are for measuring the cell impedance of the cell 110b. However, similar sequence and calculations may be applied to any cell 110 in the battery pack 310.

As an example, the battery management system 330 may determine an impedance for the cell 110b with consideration for the parasitic resistance 304b of the conducting element 320b and the parasitic resistance 304c of the conducting element 320c. As shown in FIG. 3A, during the first state (e.g., the first state 352 of FIG. 3C), the switches 114 associated with the individual cell 110b under measurement and its neighboring cells 110a and 110c are to be opened. For instance, the control circuitry 334 may generate control signals 336a, 336b, and 336c to cause the switch 114a, 114b, and 114c, respectively, to be in an opened state. While the switches 114a, 114b, and 114c are opened, the ADC 122a may measure an output voltage

$$( e . g . , represented by {V}_{ADC}^{( 1 )} )$$

of the cell 110a, the ADC 122b may measure an output voltage

$$( e . g . , represented by {V}_{ADC}^{( 2 )} )$$

of the cell 1100, and ine ADC 122c may measure an output voltage

$$( e . g . , represented by {V}_{ADC}^{( 3 )} )$$

of the cell 110c. Because the switches 114a, 114b, and 114c are in an open state, there is no current flowing through the conducting elements 302a, 302b, 302c, and 302d. Hence, in that state,

$${V}_{ADC}^{( 1 )}$$

may correspond to an open circuit voltage of the cell 110a, which voltage may be represented by

$${V}_{OCV}^{( 1 )} .$$

Similarly, in the open state,

$${V}_{ADC}^{( 2 )}$$

may correspond to an open circuit voltage the cell 110b, which may be represented by

$${V}_{OCV}^{( 2 )} ;$$

and, in the open state,

$${V}_{ADC}^{( 3 )}$$

may correspond to an open circuit voltage the cell 110c, which may be represented by

$${V}_{OCV}^{( 3 )} .$$

The processing circuitry 332 may receive readouts (or digital codes representative) of the output voltages

$${V}_{ADC}^{( 1 )} , {V}_{ADC}^{( 2 )} , and {V}_{ADC}^{( 3 )}$$

obtained during the first state.

FIG. 3B is a schematic diagram illustrating the battery cell impedance measurement configuration 300 for the stack of cells 110 during the second state after the first state, according to some aspects of the disclosure. As shown, during the second state (e.g., the second state 354 of FIG. 3C), the switch 114b associated with the individual cell 110b under measurement is to be closed while the switches 114a associated with the neighboring cell 110a and the switch 114c associated with the neighboring cell 110c are to be opened. For instance, the control circuitry 334 may generate the control signals 336a, 336b, and 336c such that the switch 114a may remain opened, the switch 114b may be closed, and the switch 114c may remain opened, respectively. While the switch 114b is closed and the switches 114a and 114c are opened, the ADC 122a may measure an output voltage

$$( e . g . , represented by {V}_{ADC}^{′ ( 1 )} )$$

of the cell 110a, the ADC 122b may measure an output voltage

$$( e . g . , represented by {V}_{ADC}^{′ ( 2 )} )$$

of the cell 110b, and the ADC 122c may measure an output voltage

$$( e . g . , represented by {V}_{ADC}^{′ ( 3 )} )$$

of the cell 110c. When the switch 114b is closed, a stimulus current 303 (shown as I_{b}) may be generated. Hence, a current shown by I_{b}′ may flow through the conducting elements 302b and 302c. The current I_{b}′ may be about the same as I_{b}.

With the current I_{b}′ flowing through the conducting element 302b, a voltage drop (e.g., represented by V_{Rp2}) may occur across the conducting element 302b due to the parasitic resistance 304b. Similarly, with the current I_{b}′ flowing through the conducting element 302c, a voltage drop (e.g., represented by V_{Rp3}) may occur across the conducting element 302c due to the parasitic resistance 304c. Accordingly, the output voltage

$${V}_{ADC}^{′ ( 1 )}$$

measured for cell 110a during the second state may include not only

$${V}_{OCV}^{( 1 )}$$

but also the voltage drop V_{Rp2} as shown below:

$${V}_{ADC}^{′ ( 1 )} = {V}_{OCV}^{( 1 )} - {V}_{Rp 2} . \qquad ( 1 )$$

In a similar way, the output voltage

$${V}_{ADC}^{′ ( 3 )}$$

measured for cell 110c during the second state may In a similar way, the output voltage include not only

$${V}_{OCV}^{( 3 )}$$

but also the voltage drop V_{Rp3} (an error) as shown below:

$${V}_{ADC}^{′ ( 3 )} = {V}_{OCV}^{( 3 )} - {V}_{Rp 3} . \qquad ( 2 )$$

The output voltage

$${V}_{ADC}^{′ ( 2 )}$$

measured for cell 110b during the second state may include not only a voltage

$$( e . g . , represented by {V}_{STIM}^{( 2 )} )$$

of the cell 110b responsive to the stimulus current 303 but also the voltage drop V_{Rp2} (an error) due to current I_{b}′ flowing through the conducting element 302b and the voltage drop V_{Rp3} (an error) due to current I_{b}′ flowing through the conducting element 302c as shown below:

$${V}_{ADC}^{′ ( 2 )} = {V}_{STIM}^{( 2 )} + {V}_{Rp 2} + {V}_{Rp 3} . \qquad ( 3 )$$

The processing circuitry 332 may receive readouts (or digital codes representative) of the output voltages

$${V}_{ADC}^{′ ( 1 )} , {V}_{ADC}^{′ ( 2 )} , and {V}_{ADC}^{′ ( 3 )}$$

obtained from the second state. The processing circuitry 332 may determine the voltage drop V_{Rp2} based on a difference between

$${V}_{ADC}^{( 1 )}$$

obtained from the first state and

$${V}_{ADC}^{′ ( 1 )}$$

obtained from the second state. In a similar way, the processing circuitry 332 may determine the voltage drop V_{Rp3} based on a difference between

$${V}_{ADC}^{( 3 )}$$

obtained from the first state and

$${V}_{ADC}^{′ ( 3 )}$$

obtained from the second state. After determining V_{Rp2} and V_{Rp3}, the processing circuitry 332 may determine

$${V}_{STIM}^{( 2 )}$$

by adjusting

$${V}_{ADC}^{′ ( 2 )}$$

with V_{Rp2} and V_{Rp3} as shown below:

$${V}_{STIM}^{( 2 )} = {V}_{ADC}^{′ ( 2 )} - {V}_{Rp 2} - {V}_{Rp 3}$$

After determining, the processing circuitry 332, the processing circuitry 332 may correlate voltage changes (between

$${V}_{OCV}^{( 2 )} and {V}_{STIM}^{( 2 )}$$

with the stimulus current 303 to determine the impedance of the cell 110b. That is, the processing circuitry 332 may combine output voltages of the neighboring cells 110a and 110c with output voltages of the individual cell 110b that is under impedance measurement before correlating with the stimulus. Mechanisms for determining the impedance based on the voltage changes and the stimulus will be discussed more fully below with reference to FIG. 4.

In general, the battery management system 330 may compensate for the impedance or voltage drop of any sense wire (conducting element 302) shared between two adjacent cells 110 and measure an impedance of a cell in the series using substantially similar mechanisms as for the cell 110b. For example, the impedance of a cell (e.g., the cell 110b) in the middle of the series with conducting elements 302 (each connecting to a different terminal of the cell) can be measured by applying a stimulus current to that cell and summing the voltages of that cell and its immediate adjacent cells (e.g., the cells 110a and 110c) before correlating the voltage change with the stimulus current for impedance calculation. Because the battery management system 330 utilizes output voltages of neighboring cells to avoid coupling between measurements (the wire impedance issue), the battery management system 330 can simultaneously measure impedance for multiple cells (e.g., stimulated cells) of the plurality of cells as long as the multiple cells are spaced apart from each other by two other cells (e.g., non-stimulated cells) of the plurality of cells.

FIG. 3C is a timing diagram 350 of control signals in the battery management system 330 for cell impedance measurements, according to some aspects of the disclosure. In FIG. 3C, the x-axis represents time in some arbitrary units. For simplicity of illustration, FIG. 3C shows impedance measurement control signals for twelve series-connected battery cells 110 in the battery pack 310. However, similar control signal pattern may be used to control any suitable number of battery cells 110 (e.g., 4, 5, 6, 7, 8, 9, 10, 11, 13, 14, or more more) in the battery pack 310 for impedance measurements. The series of twelve cells 110 in the battery pack 310 may be represented by Cell 1 to Cell 12, where Cell 1 is a beginning cell in the series and Cell 12 is a last cell in the series. Cell 1 to Cell 3 may be connected as shown in the configuration 300 of FIGS. 3A-3B. Cell 4 to Cell 12 may be connected in a similar configuration. For instance, the negative terminal of Cell 4 is connected to the positive terminal of Cell 3, the negative terminal of Cell 5 is connected to the positive terminal of Cell 4, and so on. Further, each terminal of each of the Cell 4 to Cell 12 may be connected to a conducting element (similar to the conducting elements 302) in a ladder configuration with adjacent cells sharing the same conducting element, and each cell is coupled to a series-connected switch and bleed resistor (similar to the series-connected switch 114 and bleed resistors 112) and an ADC (similar to the ADCs 122).

FIG. 3C illustrates control signals 336a to 3361, for example, generated by the control circuitry 334, to control switches 114 associated with respective battery cells. More specifically, the control signal 336a may control a switch 114 for the Cell 1, the control signal 336b may control a switch 114 for Cell 2, the control signal 336c may control a switch 114 for Cell 3, the control signal 336d may control a switch 114 for Cell 4, and so forth similar to the configuration shown in FIGS. 3A and 3B.

In the illustrated example of FIG. 3C, the battery management system 330 may simultaneously measure impedances for Cell 2, Cell 5, Cell 8, Cell 11. During a first state 352, the control circuitry 334 may configure the control signals 336a to 3361 with a logic low so that all the switches 114 associated with Cell 1 to Cell 12 are opened. While all the switches 114 associated with Cell 1 to Cell 12 are opened, each ADC may read an output voltage of a respective cell. The processing circuitry 332 may read the ADC output from each ADC. During a second state 354, the control circuitry 334 may configure the control signals 336b, 336e, 336h, and 336k with a logic high so that the switches 114 associated with Cell 2, Cell 5, Cell 8, and Cell 11, respectively, are closed so that a stimulus current may be generated for each of the Cell 2, Cell 5, Cell 8, and Cell 11 that are under impedance measurement. At the same time, the control circuitry 334 may configure the remaining control signals 336 to remain at a logic low so that the switches 114 associated with the remaining cells (the non-stimulated neighboring cells of Cell 1, Cell 3, Cell 4, Cell 6, Cell 7, Cell 9, Cell 10, and Cell 12) remain opened. While the switch 114 of each cell (e.g., Cell 2, Cell 5, Cell 8, and Cell 11) under measurement is closed and the switches 114 of corresponding neighboring cells are opened, each ADC may read an output voltage of each respective cell. The processing circuitry 332 may again read the ADC output from each ADC.

The processing circuitry 332 may determine an impedance for each individual cell (e.g., Cell 2, Cell 5, Cell 8, and Cell 11) under impedance measurement by combining output voltages of the individual cells and its neighboring cells using equations (1)-(4) discussed above. In a similar way, the battery management system 330 may simultaneously measure the cell impedance of Cell 1, Cell 4, Cell 7, and Cell 10 as a group and may simultaneously measure the cell impedance of Cell 3, Cell 6, Cell 9, and Cell 12 as a group.

As can be seen in FIGS. 3A-3C, the battery management system 330 may accurately determine an impedance for an individual cell 110 (e.g., the cell 110b) in the battery pack 310 by accounting for parasitic resistances 304 on the wires (e.g., conducting elements 302 (e.g., the conducting elements 302b and 302c) that carry the stimulus current using output voltages measured from neighboring cells 110 (e.g., as shown in equations (1)-(4)). However, the last cell 110a in the series of cell 110 may have one neighboring cell 110b at the top but no neighboring cell at the bottom. Thus, the effect of the parasitic resistance 304a Rₚ₁ may not be accounted for using the sequence shown in FIGS. 3A-3C. Accordingly, it may be beneficial to add an additional wire for the last cell 110a as shown in FIG. 3D to assist output voltage measurements for the last cells 110a.

FIG. 3D is a schematic diagram illustrating an example battery cell impedance measurement configuration 360 for the stack of cells 110, according to some aspects of the disclosure. The configuration 360 of FIG. 3D shares many elements with the configuration 300 of FIGS. 3A-3B. As such, for the sake of brevity, a discussion of these elements is not repeated, and these elements may take the form of any of the embodiments disclosed herein. The configuration 360 is substantially similar to the configuration 360 except for connections associated voltage measurements for the last cell 110a in the series or the battery pack 310.

As is shown in FIG. 3D, an additional conducting element 308 (e.g., a wire) is added, where the last cell 110a may be coupled to the ADC 122a via the conducting element 302b and 308. Further, the conducting element 302a that carries a stimulus current for the cell 110a (when the switch 114a is closed) is not coupled to the ADC 122a. That is, the conducting element 302a is not used for voltage measurement, and instead, the added conducting element 308 is used for voltage measurement. In this way, voltage measurement for the cell 110a measured by the ADC 122a may not be impacted by the parasitic resistance 304a Rₚ₁. Stated differently, the output voltage of the cell 110a is measured by the ADC 122a via the conducting element 302b and 308, and the parasitic resistance 304b Rₚ₂ from the conducting element 302b can be accounted for using the same sequence as discussed above with reference to FIGS. 3A-3C. In some examples, an additional conducting element 308 can be added at the bottom of a last cell 110 (a bottom cell) in the series but not for a beginning cell 110 in the series. In other examples, an additional conducting element 308 can be added at the top of a beginning cell 110 (a top cell) in the series but not for a last cell 110 in the series. In yet other examples, an additional conducting element 308 can be added at the top of a beginning cell 110 in the series and an additional conducting element 308 can be added at the bottom of a last cell 110 in the series.

FIG. 4 is a schematic diagram illustrating an example correlation device 400 for battery impedance measurement. The correlation device 400 can be implemented by the battery management system 120 and/or 330. As is illustrated, the correlation device 400 may include an ADC 410 coupled to a correlator 402. The correlator 402 may include a phase accumulation component 420, a memory 430, multipliers 436 and 438, a filter 450, a filter 470, a decimation component 460 and a decimation component 480. Each of the components of the correlator 402 may be implemented using software and/or hardware components. In some examples, the correlator 402 may be implemented via software executed by a processor (e.g., the processing circuitry 332).

As described herein with reference to FIGS. 3A-3B, the control circuitry 334 at the battery management system 330 may open and close each switch 114 to generate a modulated stimulus current for a corresponding cell 110. The resulting changes in cell voltages can be determined from the voltages measured by a corresponding ADC 122. These voltage changes can be correlated with the stimulus current (generated from the switching) for cell impedance calculation. In some aspects, the ADC 410 may correspond to an ADC 122 in the configuration 200 and/or configuration 300. The ADC 410 may read output voltage measurements, for example, for a corresponding cell 110 in the battery pack 310. In some aspects, the battery management system 330 may include a separate correlator 402 coupled to each ADC 122 for correlating voltage changes of a corresponding cell 110 to the stimulus current of the corresponding cell 110.

The phase accumulation component 420 may track the phase change for every ADC sample (e.g., output voltage measurements 412) based on a switching or modulation frequency of a stimulus current for the corresponding cell. In one example scenario, if the stimulus current has an excitation at every 10 ms (e.g., the stimulus current may have a square waveform with a frequency of 100 Hz), and the ADC 410 reads a measurement at every 1 ms, then the phase of the stimulus current may change by Δn=36 degrees (e.g., 360/10) for every ADC sample or measurement. Accordingly, the phase accumulation component 420 may update the phase associated with the ADC samples by Δn=36 degrees (e.g., where Δn represent a change (e.g., an increment or decrement) for each ADC sample.

The memory 430 may be any suitable memory configured to store a cosine lookup table and a sine lookup table. The cosine lookup table and the sine lookup table may have entries with increments based on the excitation frequency used for the stimulus and/or the sampling rate of the ADC 410. For example, the cosine lookup table may store cos (i×Δn), and the sine lookup table may store sine (i×Δn). Referring to the example above where the stimulus current has an excitation at every 10 ms and the ADC 410 samples (or reads) a measurement at every 1 ms, the cosine lookup table and the sine lookup table may have entries incremented at steps of Δn=36 degrees. For each ADC measurement 412 (e.g., represented by V(i)), the multiplier 436 may multiply the output voltage measurement 412 by a corresponding cosine value 432 (e.g., cosine (i×Δn)), and the multiplier 438 may multiply the output voltage measurement 412 by a corresponding sine value 434 (e.g., sine (i×Δn)).

The filter 450 may filter the ADC measurement 412 multiplied by the corresponding cosine value 432 and the decimation component 460 may apply decimation to provide an in-phase component 462 of an impedance 490 for the corresponding cell. Similarly, the filter 470 may filter the ADC measurement 412 multiplied by the corresponding sine value 434 and the decimation component 480 may apply decimation to provide a quadrature-phase component 482 of the electrical impedance 490 for the corresponding cell. The in-phase component 462 of the electrical impedance 490 may correspond to a resistive component of the electrical impedance 490 while the quadrature component 482 may correspond to a reactance (e.g., an inductive component or a capacitive component, or a combination of both) of the electrical impedance 490.

In some aspects, the filter 450 and the filter 470 may each be configured as low-pass filters. For example, the battery management system 330 may correlate the cell voltage changes with a specific harmonic of the stimulus current signal and may suppress other frequency components. Accordingly, the filter 450 and the filter 470 can improve frequency selectivity for cell impedance measurements.

In some aspects, the battery management system 330 may measure the electrical impedance of a cell 110 across a certain frequency range. Accordingly, the battery management system 330 may generate stimulus currents for the cell 110 with modulation frequencies by switching a corresponding switch 114 at multiple switching frequencies in the frequency range.

While the stimulus currents for the various cells 110 may have about the same nominal value, a mismatch in the currents can arise due to manufacturing variations in the bleed resistors 112 and/or switches 114. A mismatch in current can impact the measurement results of the electrical impedances across the cells 110. The mismatch between stimulus currents of adjacent cells 110 can be evaluated by comparing how the effects of the stimulus in each cell 110 affects the measurements of its neighboring cells 110. For instance, the battery management system 330 may generate a stimulus current with a stimulus frequency fs for the cell 110b and a stimulus current with a stimulus frequency fc for the cell 110c. The battery management system 330 may compare a digital output from the ADC 122b when cell 110b is stimulated with a stimulus frequency f_{B} with a digital output from the ADC 122c when the cell 110c is stimulated with a stimulus frequency f_{C}. To compensate for any frequency dependence of the measurement, the comparison can be repeated with stimulus frequencies f_{B} and f_{C} swapped. That is, the battery management system 330 may generate a stimulus current with a stimulus frequency f_{C} for the cell 110b and a stimulus current with a stimulus frequency f_{B} for the cell 110C. In some instances, it may be desirable to configure one of the frequencies f_{B} or C to be at direct current (DC). That is, one of the stimulus currents may be at a constant level (e.g., no switching) during the measurement.

In another aspect, instead of stimulating every third cell 110 in a plurality of cells connected in series as discussed above with reference to FIGS. 3A-3D, the battery management system 330 can apply a stimulus current simultaneously to all cells 110 in the series. Stimulating all cells 110 in the pack 310 at the same time can reduce the impact of voltage drop across the conducting elements 302 on the overall impedance measurement accuracy. Referring to the example shown in FIG. 3A or FIG. 3B where the impedance for the cell 110b is to be measured, when both bleed current switches 114a and 114b are closed at the same time, the current flowing through the conducting element 302b may be reduced to the difference (or mismatch) between the bleed current from the cell 110b and the bleed current from the cell 110a. As an example, while all switches 114 associated with the cells 110 are opened, the battery management system 330 may read an output voltage of each cell via a corresponding ADC. Subsequently, the battery management system 330 may close all switches 114 associated with the cells 110 to generate a stimulus current for each cell. While all switches associated with the cells 110 are closed, the battery management system 330 may read an output voltage of each cell via a corresponding ADC. The battery management system 330 may determine a voltage change for each cell between the time when a corresponding switch is opened and the time when the corresponding switch is closed. The battery management system 330 may correlate the voltage change at each cell with a corresponding stimulus current to determine an impedance for each cell, for example, using the scheme 400 discussed above with reference to FIG. 4.

In some aspects, the battery management system 330 may configure all cells 110 in the series within the battery pack 310 with the same stimulus frequency (e.g., stimulus current modulation frequency). In other aspects, the battery management system 330 may configure different cells 110 in the series with different frequencies. In some examples, the battery management system 330 man configure a stimulus frequency for each cell 110 such that the stimulus frequency of each cell is located at a notch frequency of each correlator 402 associated with its four nearest neighboring cells 110. Such a stimulus frequency configuration can ensure the impedance measurement of each cell 110 may not be affected by the stimulus current of the neighboring cells 110. A further advantage of this configuration is that applying different frequencies to adjacent cells 110 can introduce an extra dither into the measurement, and thus the linearity of the measurements can be improved.

### Example Scenarios Involving Other Stimulus Current Sources

In one aspect, it may be common for a battery management system (e.g., the battery management system 330) to have a processor (e.g., the processing circuitry 332) connected to measurement circuitries of a battery pack (e.g., the battery pack 310) for control and communication purposes. The processor may draw current from the battery pack. The drawn current may be a function of processing load of the processor. This processing load can be modulated, from idle to active for instance. The resulting changes in current can be used as a stimulus for the battery impedance measurement.

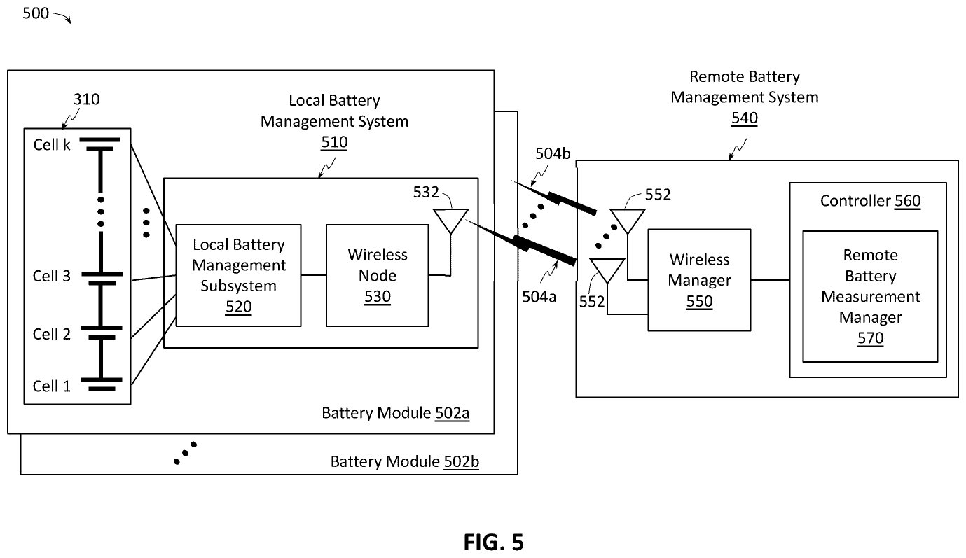

In another aspect, a battery management system may be a wireless battery management system (e.g., the wireless battery management system 500 shown in FIG. 5) in which a local battery management system may be physically connected to a battery pack (e.g., the battery pack 310) and a radio may provide communication to a network. The radio may draw a supply current from the battery pack. The drawn supply current may depend on the activities of the radio which is controlled by the processor. The supply current of the radio can be modulated to provide a stimulus current (to the battery pack) for impedance measurement.

### Example Wireless Battery Management System

In some examples, large battery packs (e.g., the battery pack 310) that are used in electric vehicles may include a large number of battery cells (e.g., the battery cells 110). In some examples, a large battery pack may include about 10 battery modules, each including about 12 battery cells connected in series. As such, a large wiring harness may be required to monitor all the individual cells. The large wiring harness may have a negative impact on the cost, weight, and reliability of the battery pack. Accordingly, it may be desirable to replace the physical wiring between the measurement electronics and the central battery monitor manager by a wireless network. While these wireless networks may generally have a lower data rate than the wired network (provided by the physical wires), these wireless networks may be lighter and more mechanically robust than the wired network.

FIG. 5 is a schematic diagram illustrating an example wireless battery management system 500, according to some aspects of the disclosure. As shown, the system 500 may include a plurality of battery modules 502 (shown as 502a to 502b), each coupled to a remote battery management system 540 via a wireless link 504 (shown as 504a to 504b). For simplicity, FIG. 5 illustrates internal components for the battery module 502a and the followings are discussed with reference to the battery module 502a. However, each of the battery module 502 may have substantially the same components and analogous descriptions can be applied to the other battery module 502.

As is shown, the battery module 502a may include a battery pack 310 and a local battery management system 510. That is, the local battery management system 510 is located locally at the battery module 502a. The battery pack 310 may include a plurality of cells 110 (shown as Cell 1 to Cell k) connected in series as discussed above with reference to FIGS. 3A-3D. In some examples, different battery modules 502 can have different number of series-connected cells 110. For instance, the battery module 502a may have twelve cells 110 connected in series while the battery module 502b may have ten cells 110 connected in series.

The local battery management system 510 may include a local battery management subsystem 520 and a wireless node 530. The local battery management subsystem 520 may include stimulus current generation circuitry, ADCs, processing circuitry, and control circuitry. In some instances, the stimulus current generation circuitry, ADCs, processing circuitry, and control circuitry may be substantially similar to the stimulus current generation circuitry 320, ADCs 122, processing circuitry 332, and control circuitry 334, respectively, as discussed above with reference to FIGS. 3A-3D. For instance, the stimulus current generation circuitry may include switches similar to the switches 114 and bleed resistors similar to the bleed resistors 112 arranged as shown in FIGS. 3A-3B and may generate stimulus currents for each of the cells 110 for impedance measurement as the switches open and closes. The control circuitry may control the switching (opening and closing) of each switch at the stimulus current generation circuitry to generate a stimulus current for a respective cell 110 for impedance measurements. Each ADC may measure the output voltages of each individual cell 110. The processing circuitry may read the cell output voltages (e.g., the ADC outputs) for each cell, for example, as the corresponding switches is opened and closed to provide the stimulus current. That is, the cell output voltages of each cell (e.g., over a certain period) may be a response waveform responsive to a corresponding stimulus current.

The local battery management subsystem 520 may provide the measured response waveforms to the wireless node 530 for wireless transmission to the remote battery management system 540. In some instances, the local battery management subsystem 520 may process the response waveforms prior to providing the response waveforms to the wireless node 530. The wireless node 530 may include a wireless transceiver and one or more antennas 532. The wireless node 530 may be configured to communicate with the remote battery management system 540 via the antenna(s) 532 over the wireless communication link 504a. The wireless node 530 may utilize any suitable wireless communication protocol (e.g., Bluetooth, WiFi, cellular protocols such as long-term evolution (LTE) and/or fifth generation (5G), a proprietary protocol, etc.), for wireless communication with the remote battery management system 540. The wireless node 530 may encode the measured response waveforms in a certain encoding format and transmit the encoded response waveforms in a certain transmission format according to a selected wireless communication protocol.

The remote battery management system 540 may include a wireless manager 550 and a controller 560 (e.g., including one or more processing elements). The wireless manager 550 may include one or more wireless transceivers and antennas 552 configured to communicate with each of the battery modules 502 via a corresponding wireless communication link 504. Similar to the wireless node 530, the wireless manager 550 may utilize any suitable wireless communication protocols (e.g., Bluetooth, WiFi, cellular protocols such as long-term evolution (LTE) and/or fifth generation (5G), a proprietary protocol, etc.), for wireless communication with the wireless node 530 at the local battery management system 510. The wireless manager 550 may receive the response waveforms or post-processed waveforms from the local battery management system 510. The wireless manager 550 may provide the received response waveforms or post-processed waveforms to the controller 560. The controller 560 may implement a remote battery measurement manager 570 to manage and compute impedances for each of the cells 110 at each of the battery modules 502.

In some aspects, the processing circuitry or processor at the local battery management subsystem 520 may include a light-weight processor (with a limited processing capability), and the controller 560 at the remote battery management system 540 may include a heavy-weight processor (with a high processing capability). In some examples, the controller 560 may be located in a cloud network with a high availability of resources.

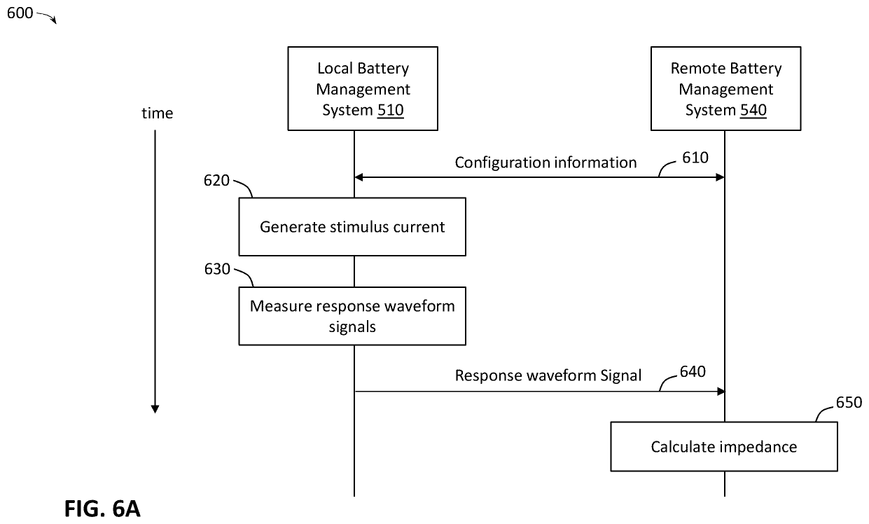

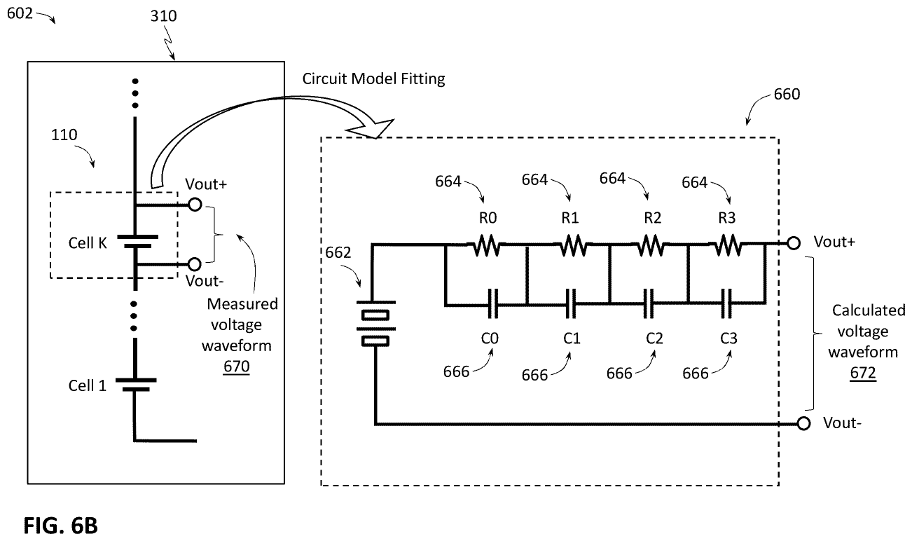

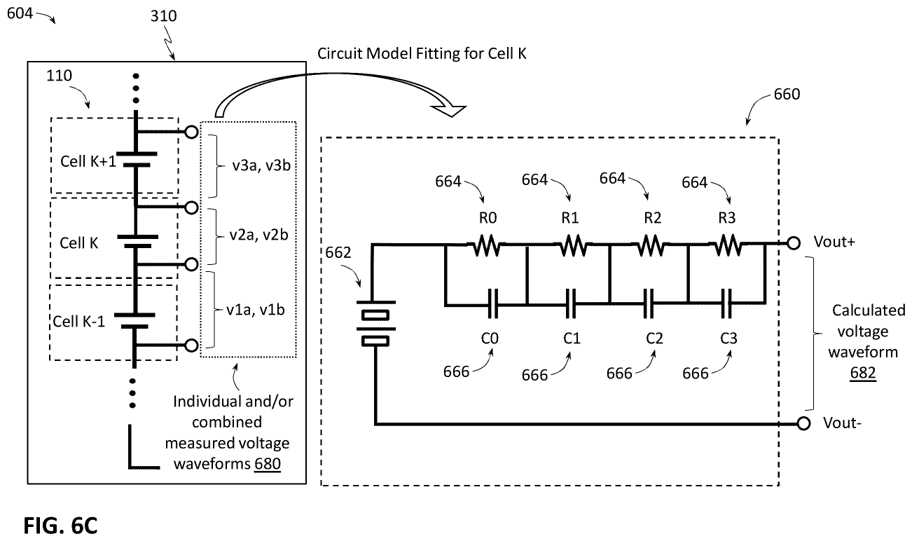

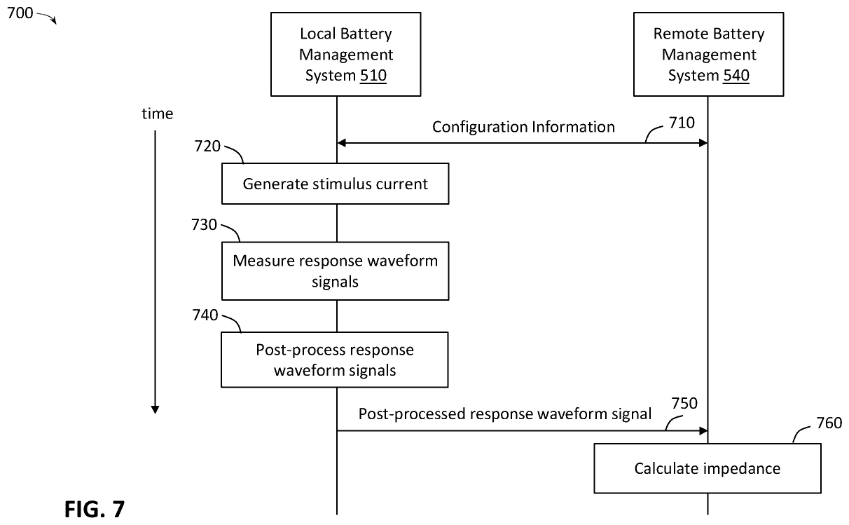

FIGS. 6A-6C and 7 are discussed in relation to FIG. 5 to illustrate operations at the local battery management system 510 and at the remote battery management system 540 and communications between the local battery management system 510 and the remote battery management system 540. At a high level, the local battery management system 510 may generate a stimulus current for each cell 110 and measure cell output voltages (e.g., waveforms) of the cell 110 in response to the stimulus current and wirelessly transmit the measured response waveforms to the remote battery management system 540. Thus, the computationally intensive impedance calculation operations may be offloaded to the remote battery management system 540. To that end, the remote battery management system 540 may receive the measured response waveforms and calculate impedances for each cell 110 based on a corresponding stimulus current. In some aspects, the remote battery management system 540 may determine the impedance of a cell 110 using a system identification approach, for example, by fitting a circuit model (or circuit parameters) to the response waveform based on the corresponding stimulus current.

FIG. 6A is a sequence diagram illustrating an example battery impedance measurement method 600, according to some aspects of the disclosure. The method 600 may be implemented between the local battery management system 510 and at the remote battery management system 540 of FIG. 5. Operations are illustrated once each and in a particular order in FIG. 6A, but the operations may be performed in parallel, reordered, and/or repeated as desired. In an example, the local battery management system 510 and the remote battery management system 540 may perform the operations of the method 600 sequentially in time as shown.

At 610, the local battery management system 510 may communicate cell impedance measurement configuration information with the remote battery management system 540 via a wireless communication link 504.

In some aspects, the remote battery management system 540 may transmit, and the local battery management system 510 may receive, the cell impedance measurement configuration information. The cell impedance measurement configuration information may be determined by the remote battery management system 540. The cell impedance measurement configuration information may include a wide variety of measurement configuration parameters. In some examples, the cell impedance measurement configuration information may include stimulus current generation parameters or stimulus waveform characteristics, such as a modulation frequency, a duty cycle, etc., for generating a stimulus current for a certain cell 110 at the module 502a. In some examples, the cell impedance measurement configuration information may include an indication of a 2-levels binary waveform for controlling a switch (e.g., the switches 114) for a certain cell 110 at the battery module 502a.

In some aspects, the local battery management system 510 may transmit, and the remote battery management system 540 may receive, the cell impedance measurement configuration information. The cell impedance measurement configuration information may be determined by the local battery management system 510. For instance, the cell impedance measurement configuration information may include stimulus waveform characteristics, such as a modulation frequency, a duty cycle, etc., used by the local battery management system 510 for generating a stimulus current for a certain cell 110. Additionally, or alternatively, the cell impedance measurement configuration information may include an indication of a number of cells 110 connected in series in the module 502a, connections of each series-connected switches (e.g., the switches 114) and bleed resistor (e.g., the bleed resistors 112) associated with each cell 110, and/or a switching frequency of each switch associated with each cell 110. In general, the cell impedance measurement configuration information communicated at 610 can be arranged in any suitable way, for example, including a separate configuration for each cell 110 at the module 502a and/or one or more configurations that may be applied to multiple cells 110.

At block 620, the local battery management system 510 may generate a stimulus current according to the communicated cell impedance measurement configuration information. In some aspects, the local battery management system 510 may open and close a switch for each corresponding cell 110 according to a modulation frequency and/or duty cycle indicated in the impedance measurement configuration information.

At block 630, the local battery management system 510 may measure waveform signals responsive to the generated stimulus currents. More specifically, the local battery management system 510 may measure cell output voltages of each cell 110 responsive to a respective stimulus current. That is, each response waveform signal may include a sequence of cell output voltages sampled by a corresponding ADC. In some examples, the local battery management system 510 may measure the cell output voltages via ADC readouts as discussed above with reference to FIGS. 3A-3D.

At 640, the local battery management system 510 may transmit the response waveform signals to the remote battery management system 540 via a wireless communication link 504. In some examples, the response waveform signal may include a first response waveform signal for Cell 1 110, a second response waveform signal for Cell 2 110, a third response waveform signal for Cell 3 110, and so forth.

At block 650, upon receiving the response waveform signals, the remote battery management system 540 may calculate impedances for each of the cells 110 (e.g., using the controller 560) based on corresponding response waveform signals and stimulus current. As an example, the remote battery management system 540 may calculate an impedance for Cell 1 110 based on the first response waveform signal and a corresponding stimulus current used for stimulating Cell 1 110. In a similar way, the remote battery management system 540 may calculate an impedance for Cell 2 110 based on the second response waveform signal and a corresponding stimulus current used for stimulating Cell 2 110.

In some aspects, as part of calculating the impedance, the remote battery management system 540 may fit a circuit model (e.g., a parametric model) to each received response waveform signal. For instance, the circuit model may take a circuit topology (e.g., the circuit topology 660 of FIG. 6B) and a stimulus (e.g., a stimulus current waveform) and create a corresponding voltage waveform. The circuit model fitting operations may include adjusting the parameter values of the circuit elements so that the modelled voltage waveforms provide a best fit to the measured waveforms. In other words, the circuit model fitting operations may take three inputs: a circuit topology, a stimulus current waveform, and a measured voltage waveform. The output of the fitting process is a set of parameter values for the elements of the given circuit topology. The resulting fitted circuit model may be used to calculate the impedance for each corresponding cell 110. In some examples, the circuit model fitting may be performed for a fixed frequency. In some examples, the calculated impedance may include an impedance spectrum (e.g., a frequency response of the impedances) and/or a transient response for a certain cell 110.

In some aspects, as part of calculating the impedance, the remote battery management system 540 may calculate a set of basis waveforms. Each basis waveform may represent the response of a different model equivalent circuit component (e.g., a resistor, capacitor, or resistor capacitor pair) associated with a corresponding stimulus current waveform. In some instances, the remote battery management system 540 may calculate the basis waveforms in a frequency domain. In other instances, the remote battery management system 540 may calculate the basis waveforms in a time domain. The remote battery management system 540 may construct a composite response waveform based on a weighted combination of each individual basis waveform. To that end, the remote battery management system 540 (or more specifically, the remote battery measurement manger 570) may utilize an optimizer to fit the weighted combination of the basis waveforms (used to build the composite response waveform) in a way that minimizes a norm of the difference between the measured (or received) response waveform and the constructed composite response waveform. That is, the remote battery management system 540 may calculate an impedance spectrum for each cell as a weighted sum of the frequency-domain basis waveforms, where the weight for each waveform is based on the weighting function or weights calculated by the optimizer. Stated differently, the remote battery management system 540 may construct an equivalent circuit model from a series combination of circuit components, where the impedance of each component is scaled by the corresponding weighting function calculated by the optimizer.

FIG. 6B illustrates an example circuit model fitting scenario 602, according to some aspects of the present disclosure. FIG. 6B is discussed in relation to FIG. 5 and FIG. 6A. For instance, the left side of FIG. 6B shows a battery pack 310 including a plurality of series-connected cells 110 (e.g., at the local management system 510), and the right side of FIG. 6B shows a circuit topology 660 used by the remote battery management system 540 for circuit model fitting operations (e.g., at 650 of the method 600).

The remote battery management system 540 may separately perform circuit model fitting for each individual cell 110 of the battery pack 310 using respective measured voltage waveforms received from the local battery management system 510. In the illustrated example of FIG. 6B, the circuit topology 660 may be an equivalent circuit model for the cell K 110 between the voltage output nodes Vout+ and Vout− of the cell K 110 shown on the left side of FIG. 6B. As shown, the circuit topology 660 includes a voltage 662 coupled to multiple pairs of parallel connected resistor 664 and capacitor 666 between Vout+ and Vout−. For simplicity of illustration, FIG. 6B illustrates four pairs of parallel connected resistor 664 and capacitor 666 (e.g., shown as R0 and C0, R1 and C1, R2 and C2, and R3 and C3). In general, the cell 110 can be modeled by any suitable number of circuit elements (e.g., resistors and/or capacitors) connected in any suitable configurations. As part of circuit model fitting, the remote battery management system 540 may adjust a set of parameter values for the resistors 664 and the capacitors 666. That is, the remote battery management system 540 may determine (or jointly optimize) resistance values for the resistors 664 and the capacitance values for the capacitors 666 such that a mathematically calculated voltage waveform 672 at Vout+ and Vout− of the circuit topology 660 based on a given stimulus current may best fit a measured waveform 670 (measured and received from the local battery management system 510).

In some aspects, the remote battery management system 540 may adjust the parameter values for one subset of the circuit elements (e.g., the resistor 664 R0 and the capacitor 666 C0) to fit a certain frequency component of the measured voltage waveform 670 and may adjust the parameter values for another subset of the circuit elements (e.g., the resistor 664 R1 and the capacitor 666 C1) to fit another frequency component of the measured voltage waveform 670. As an example, the parameter values for the resistor 664 R0 and the capacitor 666 C0 may be adjusted to fit a frequency component at about 1 Hz, the parameter values for the resistor 664 R1 and the capacitor 666 C1 may be adjusted to fit a frequency component at about 0.1 Hz, and so on.

In some aspects, the remote battery management system 540 may utilize a set (or a template) of circuit topologies with different circuit elements and/or different circuit connections for circuit model fitting. The remote battery management system 540 may calculate, for each circuit topology, a voltage waveform (e.g., by adjusting component values) based on a given stimulus current and select a circuit topology with the voltage waveform that best fit the measured voltage waveform. In some aspects, after the remote battery management system 540 determines a certain circuit topology (e.g., a first circuit topology) among the set of circuit topologies is most suitable for fitting a measured waveform for a certain cell 110, the remote battery management system 540 may continue to use the same first circuit topology for subsequent measured waveforms received for that cell 110.

In a similar way, the remote battery management system 540 may determine, for each remaining cell 110 of the battery pack 310, component values for respective circuit topology that may provide a calculated voltage waveform with a best fit to a respective measured voltage waveform received from the local battery management system 510. In some aspects, the remote battery management system 510 may select different circuit topologies for different cells 110. In some aspects, the remote battery management system 510 may utilize the same circuit topology for different cells 110 but the component values determined from the circuit model fitting can be different for different cells 110. In general, the remote battery management system 540 may perform circuit model fitting one cell 110 at a time and use any suitable circuit topology for each cell 110 and any suitable waveform fitting techniques (e.g., a least square fit).

As is described herein, the local battery management system 510 can measure cell output voltages via ADC readouts using the measurement sequence or mechanisms as discussed with reference to FIGS. 3A-3D. When the local battery management system 510 uses the measurement sequence of FIGS. 3A-3D, the local battery management system 510 may transmit individual and/or combined measured voltage waveforms to the remote battery management system 540 as shown in FIG. 6C.

FIG. 6C illustrates another example circuit model fitting scenario 604, according to some aspects of the present disclosure. The scenario 604 illustrated in FIG. 6C is substantially similar to the scenario 602 of FIG. 6B and may use the same circuit topology for simplicity's sake. However, in the scenario 604, the local battery management system 510 may measure voltage waveforms of the cell K under test (for impedance measurement) and voltage waveforms of neighboring cell K+1 and cell K−1 using the sequence as discussed above with reference to FIGS. 3A-3D. For instance, cell K under test may correspond to the cell 110b in FIGS. 3A-3B and 3D, the neighboring cell K+1 and cell K−1 may correspond to the cells 110c and 110a, respectively, in FIGS. 3A-3B and 3D. While not shown in FIG. 6C, the cells K+1, K, and K−1 may be connected to switches (e.g., the switches 116a, 116b, 116c) and bleed resistors (e.g., the bleed resistors 112a, 112b, 112c) as shown in FIGS. 3A-3B and 3D.

As an example, the local battery management system 510 may measure voltage waveform v3a of the cell K+1, voltage waveform v2a of cell K, and voltage waveform v1a of cell K−1 while all respective switches for the cells K+1, K, and K−1 are opened (e.g., during a state similar to the state in FIG. 3A and the first state 352 of FIG. 3C). The local battery management system 510 may further measure voltage waveform v3b of the cell K+1, voltage waveform v2b of cell K, and voltage waveform v1b of cell K−1 while the respective switch for cell K (under test) is closed and the respective switches for the neighboring cells K+1 and K−1 are opened (e.g., during a state similar to the state in FIG. 3B and the second state 354 of FIG. 3C). The local battery management system 510 may separately transmit each of the measured voltage waveforms v1a, v1b, v2a, v2b, v3a, and v3b to the remote battery management system 540 (e.g., at 640 of the method 600). In another example, the local battery management system 510 may combine (or pre-process) the voltage waveforms v1a, v1b, v2b, v3a, and v3b into a combined measured voltage waveform, e.g., vc, as discussed above with reference to equations (1) to (4) and transmit the waveform signal v2a and waveform signal vc to the remote battery management system 540 (e.g., at 640 of the method 600). In general, the local battery management system 510 may transmit the measured voltage waveforms v1a, v1b, v2a, v2b, v3a, and v3b in any suitable combinations to the remote battery management system 540. In some examples, the remote battery management system 540 may utilize a received voltage waveform directly to perform model fitting into the circuit topology 660 or any other suitable circuit topology (e.g., at 650 of the method 600). Alternatively, the remote battery management system 540 may post-process at least some of the received voltage waveforms and utilize the post-processed voltage waveform to perform model fitting into the circuit topology 660 (e.g., at 650 of the method 600). In general, the remote battery management system 540 may determine a calculated voltage waveform 682 based on the individual and/or combined measured voltage waveforms and/or post-processed voltage waveforms, circuit topology 660, and/or a corresponding stimulus current using substantially similar mechanisms as discussed above with reference to FIG. 6B.

FIG. 7 is a sequence diagram illustrating an example battery impedance measurement method 700, according to some aspects of the disclosure. The method 700 may be implemented between the local battery management system 510 and the remote battery management system 540 of FIG. 5. Operations are illustrated once each and in a particular order in FIG. 7, but the operations may be performed in parallel, reordered, and/or repeated as desired. Generally speaking, the method 700 may be similar to the method 600 in many respects. For instance, the operations at 710, block 720, and block 730 may be substantially similar to the operations at 610, block 620, and block 630 of the method 600. As such, for the sake of brevity, a discussion of those operations are not repeated, and those operations may take the form of any of the embodiments discussed above with respect to FIGS. 6A-6C. In an example, the local battery management system 510 and at the remote battery management system 540 may perform the operations of the method 700 sequentially in time as shown.

At block 740, after the local battery management system 510 measured the response waveform signals for each cell 110, the local battery management system 510 may further process (or post-process) the response waveform signals. For instance, the local battery management system 510 may filter the response waveform signals prior to transmission to the remote battery management system 540. More specifically, the local battery management system 510 may filter each response waveform signal by a corresponding filter, for example, to improve frequency selectivity, prior to transmitting the response waveform signals to the remote battery management system 540. In some aspects, the local battery management system 510 may perform at least some operations of the correlator 402 discussed above with reference to FIG. 4 on the measured response signal waveform signals prior to transmitting the response waveform signals to the remote battery management system 540. In another example, when the local battery management system 510 measures cell output voltages using the measurement sequence or mechanisms as discussed with reference to FIGS. 3A-3D, the local battery management system 510 may post-process response waveform signals measured from the cell 110 under test and neighboring cells 110 (immediately adjacent to the cell 110 under test) by combining at least some of the measured response waveform signals as discussed above with reference to FIG. 6C.

At 750, the local battery management system 510 may transmit the post-processed response waveform signals to the remote battery management system 540 via a wireless communication link 504.

At block 760, the remote battery management system 540 may calculate an impedance for each cell. In some aspects, the remote battery management system 540 may calculate the impedance using similar operations discussed above with reference to 650 of FIG. 6A and may utilize a circuit topology similar to the circuit topology 660 discussed above with reference to FIG. 6B. In some aspects, when the local battery management system 510 performs some operations of the correlator 402 at 740, the remote battery management system 540 may perform remaining operations of the correlator 402. In general, the operations for the impedance calculation can be split between the local battery management system 510 and the remote battery management system 540 in any suitable way.

In some aspects, the example method 600 or the example method 700 may omit communicating cell impedance measurement configuration information at 610 or 710, respectively. The remote battery management system 540 may reconstruct the stimulus current instead, for example, based on edges (or transitions) in the received response waveforms. By reconstructing the stimulus current at the remote battery management system 540, the overall system identification algorithm may be less sensitive to the timing of the stimulus generation.

While the example method 600 and the example method 700 are discussed in the context of communications and impedance measurements for the battery module 502a, similar mechanisms may be used for communications and impedance measurements for any battery module 502.

### Example Battery Impedance Measurement Methods

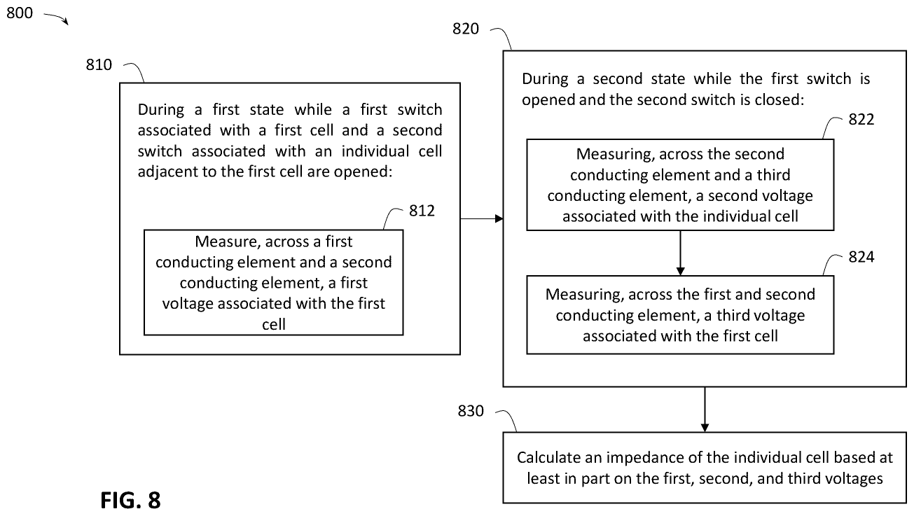

FIG. 8 is a flow diagram illustrating an example battery impedance measurement method 800, according to some aspects of the disclosure. The method 800 can be implemented by the battery management system 330 and/or the local battery management system 510. Although the operations of the method 800 may be illustrated with reference to particular embodiments of the configuration 300 disclosed herein, the method 800 may be performed using any suitable hardware components and/or software components. Operations are illustrated once each and in a particular order in FIG. 8, but the operations may be performed in parallel, reordered, and/or repeated as desired.

The example method 800 may measure battery cell impedance for a battery pack (e.g., the battery pack 310) including a plurality of battery cells (e.g., the cells 110) connected in series, for example, arranged as is shown in FIGS. 3A, 3B, and/or 5. The method 800 may use similar mechanisms as discussed above with reference to FIGS. 3A-3D, and FIGS. 5, 6A-6C, and 7.

At block 810, during a first state while a first switch associated with a first cell of the plurality of battery cells and a second switch associated with an individual cell of the plurality of battery cells adjacent to the first cell are opened, the method 800 may include the operations of block 812. The individual cell may be a cell under impedance measurement, and the first cell may be a neighboring cell (an immediate adjacent cell). As an example, the first cell and the individual cell may correspond to the cell 110b and the cell 110a, respectively, shown in FIGS. 3A-3B, and thus the first switch and the second switch may correspond to the switch 114a and the switch 114b, respectively. At block 812, a first voltage (e.g.,

$${V}_{VDC}^{( 1 )} = {V}_{OCV}^{( 1 )} )$$

associated with the first cell is measured. The first voltage may be measured across a first conducting element (e.g., the conducting element 302a) and a second conducting element (e.g., the conducting element 302b), where each of the first and second conducting elements is coupled to a different terminal of the first cell.

At block 820, during a second state while the first switch is opened and the second switch is closed, the method 800 may include the operations of block 822 and block 824. At block 822, a second voltage associated (e.g.,

$${V}_{ADC}^{′ ( 2 )} )$$

with the individual cell is measured. The second voltage may be measured across the second conducting element and a third conducting element (e.g., the conducting element 302c), where each of the second and third conducting elements is coupled to a different terminal of the individual cell. At block 824, a third voltage (e.g.,

$${V}_{ADC}^{′ ( 1 )} )$$

associated with the first cell may be measured across the first and second conducting elements.

At block 830, an electrical impedance of the individual cell is calculated based at least in part on the first voltage, the second voltage, and the third voltage.

In some aspects, as part of calculating the impedance of the individual cell at block 830, the example method 800 may adjust the measured second voltage associated with the individual cell based at least in part on the first voltage and the third voltage associated with the first cell. For example, a first voltage drop (e.g., V_{Rp2}) due to an impedance of the second conducting element may be computed by calculating a difference between the first and third voltages, and the second voltage may be adjusted by the first voltage drop (e.g., by adding the first voltage drop as discussed above with reference to equation (4)). In some aspects, the method 800 may further measure a fourth voltage (e.g.,

$${V}_{ADC}^{( 2 )} = {V}_{OCV}^{( 2 )} )$$

associated with the individual cell during the first state. The fourth voltage may be measured across the second and third conducting elements. The impedance of the individual cell calculated at 830 may be further calculated based on a voltage change between the adjusted measured second voltage (e.g.,

$${V}_{STIM}^{( 2 )} )$$

and the fourth voltage (e.g.,

$${V}_{OCV}^{( 2 )} )$$

associated with the individual cell. In some aspects, as part of calculating the impedance of the individual cell at 830, the method 800 may further correlate the adjusted second voltage with a switching frequency of the second switch.

In some aspects, the second switch and a resistor (e.g., the bleed resistor 112b) may be connected in series across the second conducting element and the third conducting element, and the electrical impedance of the individual cell calculated at 830 may be further calculated based on an amount of current (e.g., I_{b} of FIG. 3B) that flows through the resistor during the second state while the first switch is opened and the second switch is closed.

In some aspects, as part of measuring the second voltage across the second and third conducting elements at block 822, the example method 800 may further generate, a digital code representative of the second voltage using an ADC (e.g., the ADC 122b) coupled across the second and third conducting elements.

In some aspects, the example method 800 may generate the first state by opening each of the first switch associated with the first cell, the second switch associated with the individual cell, and a third switch associated with a second cell of the plurality of battery cells, where the second cell is adjacent to the individual cell. The second cell may be another neighboring cell (e.g., the cell 110c shown in FIGS. 3A-3B) immediately adjacent to the individual cell (under impedance measurement). That is, the individual cell may be a middle cell within the series-connected cells. The example method 800 may further generate the second state by opening each of the first switch and the third switch and closing the second switch. The method 800 may further measure a fourth voltage (e.g.,

$${V}_{ADC}^{( 3 )} = {V}_{OCV}^{( 3 )} )$$

associated with the second cell, across the third conducting element and a fourth conducting element (e.g., the conducting element 302d) during the first state, where each of the third and fourth conducting elements is coupled to a different terminal of the second cell. The method 800 may further measure a fifth voltage (e.g.,

$${V}_{ADC}^{′ ( 3 )} )$$

associated with the third cell. The fifth voltage may be measured across the third and fourth conducting elements during the second state. The impedance of the individual cell calculated at 830 may be further calculated based on the fourth and fifth voltages. For example, a second voltage drop (e.g., V_{Rp3}) due to an impedance of the third conducting element may be computed by calculating a difference between the fourth and fifth voltages, and the second voltage may be adjusted by the second voltage drop (e.g., by adding the second voltage drop as discussed above with reference to equation (4)).

In some aspects, the example method 800 may further include calculating an impedance of each of one or more cells of the plurality of battery cells based at least in part on a corresponding voltage measured during the second state. The one or more cells and the individual cell may be spaced apart from each other by at least two other cells of the plurality of battery cells. Further, an associated switch of each of the one or more cells may be closed during the second state while the corresponding voltage is measured. Further still, an associated switch of each adjacent cell of each of the one or more cells may be opened during the second state while the corresponding voltage is measured. For instance, if the number of cells in the plurality of battery cells connected in series is 12 (e.g., ordered from Cell 1 to Cell 12), the example method 800 may stimulate and measure Cells 1, 4, 7, 10 simultaneously, stimulate and measure Cells 2, 5, 8, 11 simultaneously, and stimulate and measure Cells 3, 6, 9, 12 simultaneously as discussed above with reference to FIG. 3C.

In some aspects, the example method 800 may further provide a first stimulus current having a first frequency to the first cell and a second stimulus current having a second frequency to the individual cell, where the second frequency is different from the first frequency. The example method 800 may further providing a third stimulus current having the second frequency to the first cell and a fourth stimulus current having the first frequency to the individual cell. Further, as part of the calculating the impedance of the individual cell at 830, the method 800 may further adjust the second voltage associated with the individual cell based on at least one of a comparison between a voltage associated with the first cell responsive to the first stimulus current and a voltage associated with the individual cell responsive to the second stimulus current; or a comparison between a voltage associated with the first cell responsive to the third stimulus current and a voltage associated with the individual cell responsive to the fourth stimulus current. By swapping the switching frequency for the first and second cells, a mismatch between the first cell and the second cell can be evaluated via the comparisons.

In some aspects, the example method 800 may further transmit, via a wireless communication link (e.g., the wireless communication links 504), an indication of the impedance of the individual cell, for example, to a remote battery management system similar to the remote battery management system 540. In other aspects, the method 800 may further transmit, via a wireless communication link (e.g., the wireless communication links 504), one or more of voltage waveforms associated with the first voltage, second voltage, or third voltage, for example, to a remote battery management system similar to the remote battery management system 540.

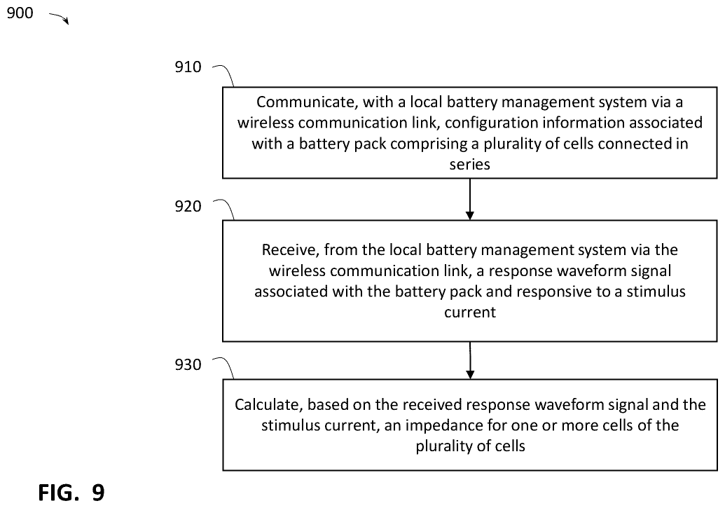

FIG. 9 is a flow diagram illustrating an example battery impedance measurement method 900, according to some aspects of the disclosure. The example method 900 can be implemented by the remote battery management system 540. The example method 900 may utilize similar mechanisms as discussed above with reference to FIGS. 5, 6A-6C, and 7. Although the operations of the example method 900 may be illustrated with reference to particular embodiments of the wireless battery management system 500 disclosed herein, the example method 900 may be performed using any suitable hardware components and/or software components. Operations are illustrated once each and in a particular order in the example method 900 shown in FIG. 9. The disclosure, however, is not limited in that respect and, in some cases, the operations may be performed in parallel, reordered, and/or repeated as desired.

At block 910, configuration information associated with a battery pack (e.g., the battery pack 310) comprising a plurality of battery cells (e.g., the cells 110) connected in series may be communicated with a local battery management system (e.g., the local battery management system 510) via a wireless communication link (e.g., the wireless communication links 504).

At block 920, a response waveform signal associated with the battery pack and responsive to a stimulus current may be received from the local battery management system via the wireless communication link. In some instances, the response waveform signal may include one or more sequences of sampled cell output voltages each corresponding to a particular cell.

At block 930, an impedance for one or more cells of the plurality of battery cells may be calculated based on the received response waveform signal and the stimulus current. In some aspects, as part of calculating the impedance for the one or more cells, the example method 900 may fit a circuit model to the received response waveform signal, for example, as discussed above with reference FIG. 6B. In some aspects, as part of the calculating the impedance for the one or more cells, the impedance may be calculated based a weighted combination of a plurality of waveforms. In some aspects, the plurality of waveforms may be as a set of basis waveforms, each corresponding to a different circuit component. In some aspects, the plurality of waveforms may include frequency domain waveforms and/or time domain waveforms. In some aspects, as part of calculating the impedance for the one or more cells, the example method 900 may include determining one or more weights for one or more of the plurality of waveforms. In some aspects, as part of calculating the impedance of the one or more cells, the example method 900 may perform the calculation further based on a comparison between the weighted combination of the plurality of waveforms and the received response waveform signal, for example, to minimize a difference between the weighted combination of the plurality of waveforms and the received response waveform signal.

In some aspects, as part of communicating the configuration information at 910, the example method 900 may transmit, to the local battery management system, a stimulus current generation configuration. In some aspects, the stimulus current generation configuration may include at least one of an indication of a waveform characteristic associated with the stimulus current or an indication of a first cell of the plurality of battery cells for stimulation by the stimulus current. In some aspects, the indication of the waveform characteristic comprises at least one of an indication of a binary waveform or a duty cycle. In some aspects, as part of communicating the configuration information at 910, the example method 900 may receive, from the local battery management system, a circuit configuration associated with the plurality of battery cells in the battery pack. In some examples, the circuit configuration may include a number of cells in the plurality of battery cells connected in series and/or arrangement of bleed resistors and/or switches associated with the battery pack. In general, the circuit configuration may include any suitable information related to generation of stimulus current for facilitating battery impedance measurement.

### Example Data Processing System

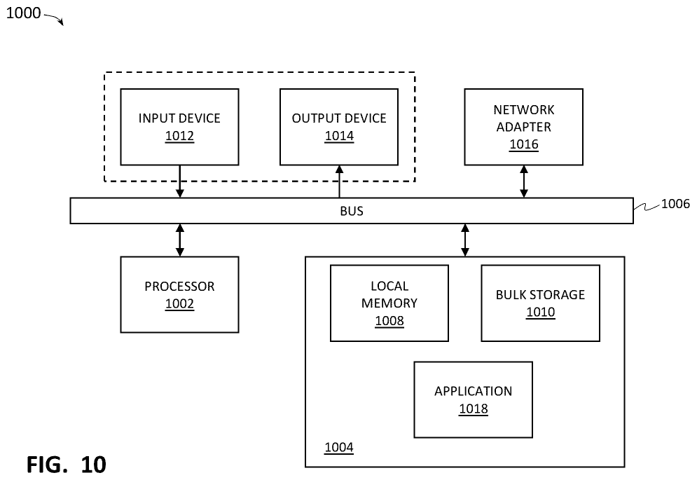

FIG. 10 is a block diagram illustrating an example data processing system 1000, according to some aspects of the present disclosure. For example, the example data processing system 1000 may be configured to implement battery impedance calculations as discussed herein. In some aspects, the example data processing system 1000 may be implemented as part of the processing circuitry 332 at the battery management system 330 discussed above with reference to FIGS. 3A-3D, 4, and 8. In some aspects, the example data processing system 1000 may be implemented as part of local battery management subsystem 520 discussed above with reference to FIGS. 5, 6A-6C, and 7-8. In some aspects, the example data processing system 1000 may be implemented as part of controller 560 at the remote battery management system 540 discussed above with reference to FIGS. 5, 6A-6C, 7, and 9.

As shown in FIG. 10, the example data processing system 1000 may include at least one processing element or processor 1002, e.g., a hardware processor 1002, coupled to memory elements 1004 through a system bus 1006. As such, the example data processing system 1000 may store program code within memory elements 1004. Further, the processor 1002 may execute the program code accessed from the memory elements 1004 via a system bus 1006. In one aspect, the data processing system may be implemented as a computer that is suitable for storing and/or executing program code. It should be appreciated, however, that the example data processing system 1000 may be implemented in the form of any system including a processor and a memory that is capable of performing the functions described within this disclosure.

In some aspects, the processor 1002 can execute software or an algorithm to perform the operations as discussed in the present disclosure, in particular operations related to battery cell impedance calculation as described herein. The processor 1002 may include any combination of hardware, software, or firmware providing programmable logic, including by way of non-limiting example a microprocessor, a digital signal processor (DSP), a field-programmable gate array (FPGA), a programmable logic array (PLA), an application specific integrated circuit (IC) (ASIC), or a virtual machine processor. The processor 1002 may be communicatively coupled to the memory element 1004, for example in a DMA configuration, so that the processor 1002 may read from or write to the memory elements 1004.

In general, the memory elements 1004 may include any suitable volatile or non-volatile memory technology, including double data rate (DDR) random-access memory (RAM), synchronous RAM (SRAM), dynamic RAM (DRAM), flash, read-only memory (ROM), optical media, virtual memory regions, magnetic or tape memory, or any other suitable technology. Unless specified otherwise, any of the memory elements discussed herein should be construed as being encompassed within the broad term “memory.” The information being measured, processed, tracked or sent to or from any of the components of the example data processing system 1000 could be provided in any database, register, control list, cache, or storage structure, all of which can be referenced at any suitable timeframe. Any such storage options may be included within the broad term “memory” as used herein. Similarly, any of the potential processing elements, modules, and machines described herein should be construed as being encompassed within the broad term “processor.” Each of the elements shown in the present figures, e.g., any elements illustrating stimulus current generation circuitry 320, control circuitry 334, wireless node 530, wireless manager 550, battery management systems 330 and 520 as shown in FIGS. 3A-3D, 4-5, 6A-6C, and 7, can also include suitable interfaces for receiving, transmitting, and/or otherwise communicating data or information in a network environment so that they can communicate with, e.g., the example data processing system 1000.

In certain example implementations, techniques for calculating battery cell impedances using processing circuitry as outlined herein may be implemented by logic encoded in one or more tangible media, which may be inclusive of non-transitory media, e.g., embedded logic provided in an ASIC, in DSP instructions, software (potentially inclusive of object code and source code) to be executed by a processor, or other similar machine, etc. In some of these instances, memory elements, such as, for example, the memory elements 1004 shown in FIG. 10, can store data or information used for the operations described herein. This includes the memory elements being able to store software, logic, code, or processor instructions that are executed to carry out the operations described herein. A processor can execute any type of instructions associated with the data or information to achieve the operations detailed herein. In one example, the processors, such as, for example, the processor 1002 shown in FIG. 10, could transform an element or an article (e.g., data) from one state or thing to another state or thing. In another example, the operations outlined herein may be implemented with fixed logic or programmable logic (e.g., software/computer instructions executed by a processor) and the elements identified herein could be some type of a programmable processor, programmable digital logic (e.g., an FPGA, a DSP, an erasable programmable read-only memory (EPROM), an electrically erasable programmable read-only memory (EEPROM)) or an ASIC that includes digital logic, software, code, electronic instructions, or any suitable combination thereof.

The memory elements 1004 may include one or more physical memory devices such as, for example, local memory 1008 and one or more bulk storage devices 1010. The local memory may refer to RAM or other non-persistent memory device(s) generally used during actual execution of the program code. A bulk storage device may be implemented as a hard drive or other persistent data storage device. The example data processing system 1000 may also include one or more cache memories (not shown) that provide temporary storage of at least some program code in order to reduce the number of times program code must be retrieved from the bulk storage device 1010 during execution.

As shown in FIG. 10, the memory elements 1004 may store an application 1018. In various embodiments, the application 1018 may be stored in the local memory 1008, the one or more bulk storage devices 1010, or apart from the local memory and the bulk storage devices. It should be appreciated that the data processing system 1000 may further execute an operating system (not shown in FIG. 10) that can facilitate execution of the application 1018. The application 1018, being implemented in the form of executable program code, can be executed by the example data processing system 1000, e.g., by the processor 1002. Responsive to executing the application, the data processing system 1000 may be configured to perform one or more operations or method acts (or operations) described herein.

Input/output (I/O) devices depicted as an input device 1012 and an output device 1014, optionally, can be coupled to the data processing system. Examples of input devices may include, but are not limited to, a keyboard, a pointing device such as a mouse, or the like. Examples of output devices may include, but are not limited to, a monitor or a display, speakers, or the like. In some aspects, the output device 1014 may be any type of screen display, such as plasma display, liquid crystal display (LCD), organic light emitting diode (OLED) display, electroluminescent (EL) display, or any other indicator, such as a dial, barometer, or LEDs. In some implementations, the system may include a driver (not shown) for the output device 1014. Input devices 1012 and/or output devices 1014 may be coupled to the data processing system either directly or through intervening I/O controllers.

In some aspects, the input and the output devices may be implemented as a combined input/output device (illustrated in FIG. 10 with a dashed line surrounding the input device 1012 and the output device 1014). An example of such a combined device is a touch sensitive display, also sometimes referred to as a “touch screen display” or simply “touch screen”. In such an embodiment, input to the device may be provided by a movement of a physical object, such as, for example, a stylus or a finger of a user, on or near the touch screen display.

A network adapter 1016 may also, optionally, be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the example data processing system 1000, and a data transmitter for transmitting data from the example data processing system 1000 to said systems, devices and/or networks. Modems, cable modems, and Ethernet cards are examples of different types of network adapter that may be used with the example data processing system 1000.

### Additional or Alternative Aspects

Numerous other aspects emerge from the foregoing detailed description and annexed drawings. Those aspects are represented by the following Clauses.

A Clause 1 includes a method for measuring impedance of a battery system including a plurality of cells connected in series. The method includes, during a first state while a first switch associated with a first cell of the plurality of cells and a second switch associated with an individual cell of the plurality of cells adjacent to the individual cell are opened, measuring, across a first conducting element and a second conducting element, a first voltage associated with the first cell, where each of the first and second conducting elements is coupled to a different terminal of the first cell. The method further includes, during a second state while the first switch is opened and the second switch is closed, measuring, across the second conducting element and a third conducting element, a second voltage associated with the individual cell, where each of the second and third conducting elements is coupled to a different terminal of the individual cell; and measuring, across the first and second conducting elements, a third voltage associated with the first cell. The method further includes calculating an impedance of the individual cell based at least in part on the first, second, and third voltages.

In a Clause 2, the method of Clause 1 can optionally or additionally include where the calculating the impedance of the individual cell includes adjusting the measured second voltage associated with the individual cell based at least in part on the first voltage and the third voltage associated with the first cell.

In a Clause 3, the method of any of Clauses 1 to 2 can optionally or additionally include measuring, across the second conducting element and the third conducting element during the first state, a fourth voltage associated with the individual cell, where the calculating the impedance of the individual cell is further based on a voltage change between the adjusted measured second voltage and the fourth voltage associated with the individual cell.

In a Clause 4, the method any of Clauses 1 to 3 can optionally or additionally include where the calculating the impedance of the individual cell further includes correlating the adjusted second voltage with a switching frequency of the second switch.

In a Clause 5, the method any of Clauses 1 to 4 can optionally or additionally include where the second switch and a resistor are connected in series across the second conducting element and the third conducting element; and the calculating the impedance of the individual cell is further based on an amount of current flowing through the resistor during the second state while the first switch is opened and the second switch is closed.

In a Clause 6, the method any of Clauses 1 to 5 can optionally or additionally include where the measuring the second voltage across the second conducting element and third conducting element include generating, via an analog-to-digital converter (ADC) coupled across the second and third conducting elements, a digital code representative of the second voltage.

In a Clause 7, the method of any of Clause 1 to 6 can optionally or additionally include generating the first state by opening each of the first switch associated with the first cell, the second switch associated with the individual cell, and a third switch associated with a second cell of the plurality of cells, where the second cell is adjacent to the individual cell; generating the second state by opening each of the first switch and the third switch to open and closing the second switch; measuring, across the third conducting element and a fourth conducting element during the first state, a fourth voltage associated with the second cell, where each of the third and fourth conducting elements is coupled to a different terminal of the second cell; and measuring, across the third and fourth conducting elements during the second state, a fifth voltage associated with the third cell, where the calculating the impedance of the individual cell is further based on the fourth and fifth voltages.

In a Clause 8, the method of any of Clauses 1 to 7 can optionally or additionally include calculating an impedance of each of one or more cells of the plurality of cells based at least in part on a corresponding voltage measured during the second state, where the one or more cells and the individual cell are spaced apart from each other by at least two other cells of the plurality of cells, and where an associated switch of each of the one or more cells is closed during the second state while the corresponding voltage is measured, and where an associated switch of each adjacent cell of each of the one or more cells is opened during the second state while the corresponding voltage is measured.

In a Clause 9, the method of any of Clause 1 to 8 can optionally or additionally include providing a first stimulus current having a first frequency to the first cell; providing a second stimulus current having a second frequency to the individual cell, the second frequency different from the first frequency; providing a third stimulus current having the second frequency to the first cell; providing a fourth stimulus current having the first frequency to the individual cell, where the calculating the impedance of the individual cell includes adjusting the second voltage associated with the individual cell based on at least one of a comparison between a voltage associated with the first cell responsive to the first stimulus current and a voltage associated with the individual cell responsive to the second stimulus current; or a comparison between a voltage associated with the first cell responsive to the third stimulus current and a voltage associated with the individual cell responsive to the fourth stimulus current.

In a Clause 10, the method of any of Clauses 1 to 9 can optionally or additionally include transmitting, via a wireless communication link, an indication of the calculated impedance of the individual cell.

A Clause 11 includes a method for providing battery impedance measurement performed by a remote battery management system, the method including communicating, with a local battery management system via a wireless communication link, configuration information associated with a battery pack including a plurality of cells connected in series; receiving, from the local battery management system via the wireless communication link, a response waveform signal associated with the battery pack and responsive to a stimulus current; and calculating, based on the received response waveform signal and the stimulus current, an impedance for one or more cells of the plurality of cells.

In a Clause 12, the method of Clause 11 can optionally or additionally include where the calculating the impedance for the one or more cells includes fitting a circuit model to the received response waveform signal.

In a Clause 13, the method of any of Clauses 11 to 12 can optionally or additionally include where the calculating the impedance for the one or more cells is further based on a weighted combination of a plurality of waveforms.

In a Clause 14, the method of any of Clauses 11 to 13 can optionally or additionally include where each of the plurality of waveforms for calculating the impedance for the one or more cells is associated with a different circuit component.

In a Clause 15, the method of any of Clauses 11 to 14 can optionally or additionally include where the plurality of waveforms for calculating the impedance for the one or more cells include at least one of a frequency domain waveform or a time domain waveform.

In a Clause 16, the method of any of Clauses 11 to 15 can optionally or additionally include where the receiving the response waveform signal includes receiving, from the local battery management system via the wireless communication link, a first response waveform signal associated with a first cell of the plurality of cells; and receiving, from the local battery management system via the wireless communication link, a second response waveform signal associated with a second cell of the plurality of cells, the second cell adjacent to the first cell; and the calculating the impedance for the one or more cells includes processing the first response waveform signal and the second response waveform signal to generate a processed waveform signal; and fitting a circuit model to the processed waveform signal.

In a Clause 17, the method of any of Clauses 11 to 16 can optionally or additionally include where the calculating the impedance for the one or more cells includes determining one or more weights for one or more of the plurality of waveforms.

In a Clause 18, the method of any of Clauses 11 to 17 can optionally or additionally include where the calculating the impedance of the one or more cells is further based on a comparison between the weighted combination of the plurality of waveforms and the received response waveform signal.

In a Clause 19, the method of any of Clauses 11 to 18 can optionally or additionally include where the communicating the configuration information includes transmitting, to the local battery management system, a stimulus current configuration.

In a Clause 20, the method of any of Clauses 11 to 19 can optionally or additionally include where the stimulus current configuration includes at least one of an indication of a waveform characteristic associated with the stimulus current; or an indication of a first cell of the plurality of cells for stimulation by the stimulus current.

In a Clause 21, the method of any of Clauses 11 to 20 can optionally or additionally include where the indication of the waveform characteristic includes at least one of an indication of a binary waveform or a duty cycle.

In a Clause 22, the method of any of Clauses 11 to 21 can optionally or additionally include where the communicating the configuration information includes receiving, from the local battery management system, a circuit configuration associated with the plurality of cells in the battery pack.

A Clause 23 includes a system including one or more processing elements to communicate, with a local battery management system via a wireless communication link, configuration information associated with a battery pack including a plurality of cells connected in series; receive, from the local battery management system via the wireless communication link, a response waveform signal associated with the battery pack and responsive to a stimulus current; and calculate, based on the received response waveform signal and the stimulus current, an impedance for one or more cells of the plurality of cells.

In a Clause 24, the system of Clause 23 can optionally or additionally include where the one or more processing elements calculates the impedance for the one or more cells based on a weighted combination of a plurality of waveforms, and where each of the plurality of waveforms is associated with a different circuit component.

In a Clause 25, the system of any of Clauses 23 to 24 can optionally or additionally include where the plurality of waveforms for calculating the impedance for the one or more cells include at least one of frequency domain waveforms or time domain waveforms.

In a Clause 26, the system of any of Clauses 23 to 25 can optionally or additionally include where the one or more processing elements communicates the configuration information by transmitting, to the local battery management system, a stimulus current configuration.

In a Clause 27, the system of any of Clauses 23 to 26 can optionally or additionally include, where the one or more processing elements communicates the configuration information by receiving, from the local battery management system, a circuit configuration associated with the plurality of cells in the battery pack.

While embodiments of the present disclosure were described above with references to example implementations as shown in FIGS. 1-2, 3A-3D, and 4-5, 6A-6C, and 710, a person skilled in the art will realize that the various teachings described above are applicable to a large variety of other implementations.

In certain contexts, the features discussed herein can be applicable to automotive systems, safety-critical industrial applications, medical systems, scientific instrumentation, wireless and wired communications, radio, radar, industrial process control, audio and video equipment, current sensing, instrumentation (which can be highly precise), and other digital-processing-based systems.

In the discussions of the embodiments above, components of a system, such as switches, resistors, filters, decimation components, multipliers, ADCs, and/or other components can readily be replaced, substituted, or otherwise modified in order to accommodate particular circuitry needs. Moreover, it should be noted that the use of complementary electronic devices, hardware, software, etc., offer an equally viable option for implementing the teachings of the present disclosure related to battery impedance measurements, in various communication systems.

Parts of various systems for battery impedance measurements in accordance with aspects of this disclosure can include electronic circuitry to perform the functions described herein. In some cases, one or more parts of the system can be provided by a processor specially configured for carrying out the functions described herein. For instance, the processor may include one or more application specific components, or may include programmable logic gates which are configured to carry out the functions describe herein. The circuitry can operate in analog domain, digital domain, or in a mixed-signal domain. In some instances, the processor may be configured to carrying out the functions described herein by executing one or more instructions stored on a non-transitory computer-readable storage medium.

In one example, any number of electrical circuits of the present figures may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of DSPs, microprocessors, supporting chipsets, etc.), computer-readable non-transitory memory elements, etc. can be suitably coupled to the board based on particular configuration needs, processing demands, computer designs, etc. Other components such as external storage, additional sensors, controllers for audio/video display, and peripheral devices may be attached to the board as plug-in cards, via cables, or integrated into the board itself. In various embodiments, the functionalities described herein may be implemented in emulation form as software or firmware running within one or more configurable (e.g., programmable) elements arranged in a structure that supports these functions. The software or firmware providing the emulation may be provided on non-transitory computer-readable storage medium comprising instructions to allow a processor to carry out those functionalities.

In another example, the electrical circuits of the present figures may be implemented as stand-alone modules (e.g., a device with associated components and circuitry configured to perform a specific application or function) or implemented as plug-in modules into application specific hardware of electronic devices. Note that particular embodiments of the present disclosure may be readily included in a system on chip (SOC) package, either in part, or in whole. An SOC represents an IC that integrates components of a computer or other electronic system into a single chip. It may contain digital, analog, mixed-signal, and often RF functions: all of which may be provided on a single chip substrate. Other embodiments may include a multi-chip-module (MCM), with a plurality of separate ICs located within a single electronic package and configured to interact closely with each other through the electronic package.

It is noted that all of the specifications, dimensions, and relationships outlined herein (e.g., the number of components of the apparatuses and/or battery management systems shown in FIGS. 3A-3B and 5) have only been offered for purposes of example and teaching only. Such information may be varied considerably without departing from the spirit of the present disclosure, or the scope of the appended claims. It should be appreciated that the system can be consolidated in any suitable manner. Along similar design alternatives, any of the illustrated circuits, components, modules, and elements of the present figures may be combined in various possible configurations, all of which are clearly within the broad scope of this specification. In the foregoing description, example embodiments have been described with reference to particular processor and/or component arrangements. Various modifications and changes may be made to such embodiments without departing from the scope of the appended claims. The description and drawings are, accordingly, to be regarded in an illustrative rather than in a restrictive sense.

It is also noted that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

It is also noted that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments. Also, as used herein, including in the claims, “or” as used in a list of items (for example, a list of items prefaced by a phrase such as “at least one of” or “one or more of”) indicates an inclusive list such that, for example, a list of [at least one of A, B, or C] means A or B or C or AB or AC or BC or ABC (i.e., A and B and C).

Various aspects of the illustrative embodiments are described using terms commonly employed by those skilled in the art to convey the substance of their work to others skilled in the art. For example, the term “connected” means a direct electrical connection between the things that are connected, without any intermediary devices/components, while the term “coupled” means either a direct electrical connection between the things that are connected, or an indirect connection through one or more passive or active intermediary devices/components. In another example, the term “circuit” means one or more passive and/or active components that are arranged to cooperate with one another to provide a desired function. Also, as used herein, the terms “substantially,” “approximately,” “about,” etc., may be used to generally refer to being within +/−20% of a target value, e.g., within +/−10% of a target value, based on the context of a particular value as described herein or as known in the art. Numerous other changes, substitutions, variations, alterations, and modifications may be ascertained to one skilled in the art and it is intended that the present disclosure encompass all such changes, substitutions, variations, alterations, and modifications as falling within the scope of the examples and appended claims. Note that all optional features of the apparatus described above may also be implemented with respect to the method or process described herein and specifics in the examples may be used anywhere in one or more embodiments.

What is claimed is:

1. A method for measuring impedance of a battery system, the method comprising:
during a first state while a first switch associated with a first cell of a plurality of cells of the battery system and a second switch associated with an individual cell of the plurality of cells are opened, the first cell being adjacent to the individual cell and the plurality of cells being connected in series:
measuring, across a first conducting element and a second conducting element, a first voltage associated with the first cell, wherein each of the first conducting element and the second conducting element is coupled to a different terminal of the first cell;
during a second state while the first switch is opened and the second switch is closed;
measuring, across the second conducting element and a third conducting element, a second voltage associated with the individual cell, wherein each of the second conducting element and the third conducting element is coupled to a different terminal of the individual cell; and
measuring, across the first conducting element and the second conducting element, a third voltage associated with the first cell; and
calculating an impedance of the individual cell based at least in part on the first voltage, the second voltage, and the third voltage.

2. The method of claim 1, wherein the calculating the impedance of the individual cell comprises adjusting the measured second voltage associated with the individual cell based at least in part on the first voltage and the third voltage associated with the first cell.

3. The method of claim 1, further comprising:
measuring, across the second conducting element and the third conducting element during the first state, a fourth voltage associated with the individual cell,
wherein the calculating the impedance of the individual cell is further based on a voltage change between the adjusted measured second voltage and the fourth voltage associated with the individual cell.

4. The method of claim 1, wherein:
the second switch and an electrical component are connected in series across the second conducting element and the third conducting element, the electrical component including a resistive element, an inductive element, or a combination of the resistive element and the inductive element; and
the calculating the impedance of the individual cell is further based on an amount of current flowing through the electric element during the second state while the first switch is opened and the second switch is closed.

5. The method of claim 1, wherein the measuring the second voltage across the second and third conducting elements comprises:
generating, via an analog-to-digital converter (ADC) coupled across the second conducting element and the third conducting element, a digital code representative of the second voltage.

6. The method of claim 1, further comprising:
generating the first state by opening each of the first switch associated with the first cell, the second switch associated with the individual cell, and a third switch associated with a second cell of the plurality of cells, wherein the second cell is adjacent to the individual cell;
generating the second state by opening each of the first switch and the third switch and closing the second switch;
measuring, across the third conducting element and a fourth conducting element during the first state, a fourth voltage associated with the second cell, wherein each of the third conducting element and the fourth conducting element is coupled to a different terminal of the second cell; and
measuring, across the third conducting element and the fourth conducting element during the second state, a fifth voltage associated with the second cell,
wherein the calculating the impedance of the individual cell is further based on the fourth voltage and the fifth voltage.

7. The method of claim 1, further comprising:
calculating an impedance of each of one or more cells of the plurality of cells based at least in part on a corresponding voltage measured during the second state,
wherein the one or more cells and the individual cell are spaced apart from each other by at least two other cells of the plurality of cells, and
wherein an associated switch of each of the one or more cells is closed during the second state while the corresponding voltage is measured, and
wherein an associated switch of each adjacent cell of each of the one or more cells is opened during the second state while the corresponding voltage is measured.

8. The method of claim 1, further comprising transmitting, via a wireless communication link, an indication of the impedance of the individual cell.

9. The method of claim 1, further comprising providing battery impedance measurements, the providing comprising:
communicating, with a battery management system via a wireless communication link, configuration information associated with a battery pack comprising a plurality of cells connected in series;
receiving, by a second battery management system, from the battery management system via the wireless communication link, a response waveform signal associated with the battery pack and responsive to a stimulus current, wherein the second battery management system is remotely located relative to the battery management system; and
calculating, by the second battery management system, based on the received response waveform signal and the stimulus current, a second impedance for one or more cells of the plurality of cells.

10. The method of claim 9, wherein the calculating the second impedance comprises fitting a circuit model to the received response waveform signal.

11. The method of claim 9, wherein the calculating the second impedance is further based on a weighted combination of a plurality of waveforms.

12. The method of claim 9, wherein the plurality of waveforms includes at least one of a frequency domain waveform or a time domain waveform.

13. The method of claim 9, wherein:
the receiving the response waveform signal comprises:
receiving, from the battery management system via the wireless communication link, a first response waveform signal associated with a first cell of the plurality of cells; and
receiving, from the battery management system via the wireless communication link, a second response waveform signal associated with a second cell of the plurality of cells, the second cell adjacent to the first cell; and
the calculating the impedance comprises:
generating a particular waveform signal by processing the first response waveform signal and the second response waveform signal; and
fitting a circuit model to the particular waveform signal.

14. The method of claim 9, wherein the communicating the configuration information comprises transmitting, by the second battery management system, to the battery management system, a stimulus current configuration.

15. The method of claim 9, wherein the communicating the configuration information comprises receiving, by the second battery management system, from the battery management system, a circuit configuration associated with the plurality of cells in the battery pack.

16. A system comprising:
one or more processing elements to:
communicate, with a local battery management system via a wireless communication link, configuration information associated with a battery pack comprising a plurality of cells connected in series;
receive, from the local battery management system via the wireless communication link, a response waveform signal associated with the battery pack and responsive to a stimulus current; and
calculate, based on the received response waveform signal and the stimulus current, an impedance for one or more cells of the plurality of cells.

17. The system of claim 16, wherein the one or more processing elements calculates the impedance for the one or more cells based on a weighted combination of a plurality of waveforms, and wherein each of the plurality of waveforms is associated with a respective circuit component.

18. The system of claim 17, wherein the plurality of waveforms includes at least one of a frequency domain waveform or a time domain waveform.

19. The system of claim 16, wherein the one or more processing elements communicates the configuration information by transmitting, to the local battery management system, a stimulus current configuration.

20. The system of claim 16, wherein the one or more processing elements communicates the configuration information by receiving, from the local battery management system, a circuit configuration associated with the plurality of cells in the battery pack.
